(19) United States
(12) Patent Application Publication
(10) Pub. No.: US 2025/0255138 A1
(43) Pub. Date: Aug. 7, 2025

(54) DISPLAY DEVICE

(71) Applicant: Electronics and Telecommunications Research Institute, Daejeon (KR)

(72) Inventors: Chan-mo KANG, Daejeon (KR); Hyunsu CHO, Daejeon (KR); Sukyung CHOI, Daejeon (KR); Byoung-Hwa KWON, Daejeon (KR); Gi Heon KIM, Daejeon (KR); Jin Wook SHIN, Daejeon (KR); Nam Sung CHO, Daejeon (KR)

(73) Assignee: Electronics and Telecommunications Research Institute, Daejeon (KR)

(21) Appl. No.: 18/986,069

(22) Filed: Dec. 18, 2024

(30) Foreign Application Priority Data
Feb. 7, 2024 (KR) 10-2024-0018916
Nov. 4, 2024 (KR) 10-2024-0154645

(51) Int. Cl. H10K 59/38; H10K 59/80

(52) U.S. Cl. CPC H10K 59/38; H10K 59/877

(57) ABSTRACT

Provided is a display device including a backplane, a light source on the backplane, a quantum dot pattern on the light source, a transparent pattern disposed on the light source and spaced apart from the quantum dot pattern in a first direction parallel to an upper surface of the backplane, and a reflection pattern between the quantum dot pattern and the transparent pattern.

### CROSS-REFERENCE TO RELATED APPLICATIONS

This U.S. non-provisional patent application claims priority under 35 U.S.C. § 119 of Korean Patent Application Nos. 10-2024-0018916, filed on Feb. 7, 2024, and 10-2024-0154645, filed on Nov. 4, 2024, the entire contents of which are hereby incorporated by reference.

### BACKGROUND

The present disclosure herein relates to a display device including a quantum dot pattern.

The advancement of the information society has brought about a rising demand for displays for display information. Accordingly, various displays such as a liquid crystal display (LCD), electronic paper (e-paper), an organic light-emitting display (OLED), and a microdisplay have been developed and utilized.

Quantum dot displays offering higher color purity than OLED and enabling solution-based processes have been the subject of intense research efforts in recent times.

### SUMMARY

The present disclosure provides a display device exhibiting high luminous efficiency.

The present disclosure provides a display device exhibiting high color reproducibility.

The present disclosure provides a display device exhibiting high resolution.

An embodiment of the inventive concept provides a display device including a backplane, a light source on the backplane, a quantum dot pattern on the light source, a transparent pattern disposed on the light source and spaced apart from the quantum dot pattern in a first direction parallel to an upper surface of the backplane, and a reflection pattern between the quantum dot pattern and the transparent pattern.

In an embodiment, the transparent pattern may include at least one of an inorganic thin film, an organic thin film, or an organic-inorganic composite thin film, or a combination thereof.

In an embodiment, the quantum dot pattern may include a quantum dot. The quantum dot may include at least one of a Group II-VI compound, a Group III-V compound, a Group IV-VI compound, a Group I-III-VI compound, a Group IV element, or a Group IV compound, or a combination thereof.

In an embodiment, the reflection pattern may include at least one of a metal element, a metal alloy, a transition metal oxide, a metal nitride, or an inorganic thin film, or a combination thereof.

In an embodiment, the light source may be a blue light source.

In an embodiment, the light source may be a blue-green light source.

In an embodiment, the display device may further include a scattering pattern on the transparent pattern, and a color filter on the quantum dot pattern.

In an embodiment, the scattering pattern may include a scattering agent. The scattering agent may include at least one of titanium oxide (TiO₂), zinc oxide (ZnO), tin oxide (SnO), silicon oxide (SiO), nickel oxide (NiO), magnesium oxide (MgO), zirconium oxide (ZrO₂), barium titanate (BaTiO₃), silicon carbide (SiC), boron nitride (BN), aluminum nitride (AlN), gallium nitride (GaN), zinc sulfide (ZnS), copper chloride (CuCl), strontium titanate (SrTiO₃), or lithium niobate (LiNbO₃), or a combination thereof.

In an embodiment, the display device may further include a blue color filter on the transparent pattern, a green color filter on the transparent pattern, and a red color filter on the quantum dot pattern.

In an embodiment, the quantum dot pattern and the transparent pattern may be provided in plurality. The quantum dot pattern and the transparent pattern may be alternately disposed in the first direction.

In an embodiment, the transparent pattern may be configured such that a width of an upper surface in the first direction is equal to or greater than a width of a lower surface.

In an embodiment, the quantum dot pattern may be configured such that a width of a lower surface in the first direction is equal to or greater than a width of an upper surface.

In an embodiment, the quantum dot pattern may be provided in plurality, and the plurality of quantum dot patterns may be spaced apart. The quantum dot pattern may be disposed in a zigzag pattern diagonally between the first direction and a second direction perpendicular to the first direction.

In an embodiment of the inventive concept, a display device includes a backplane, and a plurality of pixels on the backplane. The plurality of pixels may each include a first sub-pixel and a second sub-pixel. The first sub-pixel may include a quantum dot pattern on the backplane, a reflection pattern surrounding a side surface of the quantum dot pattern, and a first color filter on the quantum dot pattern. The second sub-pixel may include the transparent pattern on the backplane. The quantum dot pattern and the transparent pattern may be spaced apart with the reflection pattern therebetween.

In an embodiment, the second sub-pixel may further include a scattering pattern on the transparent pattern.

In an embodiment, the second sub-pixel may further include a second color filter on the transparent pattern. The first color filter and the second color filter may be different in color.

In an embodiment of the inventive concept, a display device includes a backplane, a light source on the backplane, a quantum dot pattern on the light source, a transparent pattern disposed on the light source and spaced apart from the quantum dot pattern in a first direction parallel to an upper surface of the backplane, and a reflection pattern between the quantum dot pattern and the transparent pattern. The quantum dot pattern may be provided in plurality, and the plurality of quantum dot patterns may be spaced apart and disposed in a zigzag pattern diagonally between the first direction and a second direction perpendicular to the first direction. The reflection pattern may be provided in plurality and the plurality of reflection patterns may be spaced apart and disposed in a zigzag pattern diagonally. The transparent pattern may be provided in plurality, and the plurality of reflection patterns may have lower surfaces connected and upper surfaces disposed in a zigzag pattern diagonally.

In an embodiment, the quantum dot pattern and the transparent pattern may be alternately disposed in the first direction and the second direction.

In an embodiment, the display device may further include a scattering pattern on the transparent pattern, and a color filter on the quantum dot pattern. The quantum dot pattern may include a green quantum dot pattern and a red quantum dot pattern. The color filter may include a green color filter and a red color filter.

In an embodiment, the display device may further include a first color filter on the transparent pattern, and a second color filter on the quantum dot pattern. The first color filter and the second color filter may be different in color.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a plan view showing a display device according to some embodiments of the inventive concept;

FIGS. 2A to 2C are plan views showing region A of FIG. 1;

FIG. 3 is a plan view showing pixels of FIG. 1;

FIG. 4A is a cross-sectional view taken along line A-A′ of FIG. 3;

FIG. 4B is a cross-sectional view taken along line B-B′ of FIG. 3;

FIGS. 5A to 5C are plan views showing pixels that may be included in a display device according to some embodiments of the inventive concept;

FIG. 6 is a plan view showing a display device according to some embodiments of the inventive concept;

FIG. 7 is a plan view showing pixels of FIG. 6;

FIG. 8A shows a method for manufacturing a display device according to some embodiments of the inventive concept in FIG. 1;

FIG. 8B shows a method for manufacturing a display device according to some embodiments of the inventive concept in FIG. 1;

FIGS. 9A to 13B show a method for manufacturing a display device according to some embodiments of the inventive concept in FIG. 1;

FIG. 14 is a plan view showing a display device according to some embodiments of the inventive concept;

FIGS. 15A to 15C are plan views showing region B of FIG. 14;

FIG. 16 is a plan view showing pixels of FIG. 14;

FIG. 17A is a cross-sectional view taken along line A-A′ of FIG. 16;

FIG. 17B is a cross-sectional view taken along line B-B′ of FIG. 16;

FIGS. 18A to 18C are plan views showing pixels that are included in a display device according to some embodiments of the inventive concept;

FIG. 19 is a plan view showing a display device according to some embodiments of the inventive concept;

FIG. 20 is a plan view showing pixels of FIG. 19;

FIG. 21A shows a method for manufacturing a display device according to some embodiments of the inventive concept in FIG. 14;

FIG. 21B shows a method for manufacturing a display device according to some embodiments of the inventive concept in FIG. 14; and

FIGS. 22A to 26B show a method for manufacturing a display device according to some embodiments of the inventive concept in FIG. 14.

### DETAILED DESCRIPTION

In order to facilitate sufficient understanding of the configuration and effects of this disclosure, preferred embodiments of the disclosure will be described with reference to the accompanying drawings. However, the disclosure is not limited to the embodiments set forth below, and may be embodied in various forms and modified in many alternate forms. Rather, these embodiments are provided so that this disclosure will be thorough and complete, and will fully convey the scope of the disclosure to those skilled in the art to which the disclosure pertains. In the accompanying drawings, elements are shown to be enlarged from the actual size thereof for convenience of description, and the ratio of each element may be exaggerated or reduced.

Like reference numerals refer to substantially like elements throughout.

In the following description, detailed descriptions of components and functions known in the technical field of the disclosure may be skipped if they are not related to core components of the disclosure. The meanings of the terms described herein should be understood as follows.

Shapes, sizes, ratios, angles, numbers, and the like disclosed in the drawings of the disclosure are illustrative, so that the disclosure is not limited to the illustrated details.

In addition, in describing the disclosure, when it is determined that a detailed description of a related known technology may unnecessarily obscure the gist of the disclosure, the detailed description will be skipped.

When the terms ‘include,’ ‘have,’ ‘consist of,’ and the like are used herein, other parts may be added unless ‘only’ is used. Elements of a singular form may include elements plural forms unless the context clearly indicates otherwise.

In interpreting elements, it is to be construed as including an error range even if there is no separate explicit recitation.

When the description is of a positional relationship, e.g., when a positional relationship between two portions is described by ‘on˜,’ ‘upper˜,’ ‘lower˜,’ ‘next to˜,’ etc., one or more other portions may be disposed between the two portions unless ‘right’ or ‘directly’ is used.

When the description is of a temporal relationship, e.g., when a temporal antecedent relationship is described by ‘afterward,’ ‘after˜,’ ‘subsequent to˜,’ ‘following˜,’ ‘before˜,’ etc., it may also include a case of a non-continuous temporal relationship unless ‘immediately’ or ‘directly’ is used.

It will be understood that, although the terms ‘first,’ ‘second,’ etc., are used herein to describe various elements, these elements should not be limited by these terms. These terms are only used to distinguish one element from another. Therefore, a first element mentioned hereinafter may be a second element within the technical spirit of the disclosure.

The term “at least one” should be understood as including all possible combinations from one or more related items. For example, the meaning of “at least one of a first item, a second item, and a third item” may mean not only the first item, the second item, or the third item itself, but also all possible combinations of items to be proposed from two or more of the first item, the second item, and the third item.

Hereinafter, preferred embodiments of the disclosure will be described in detail with reference to the accompanying drawings.

### [Display Device]

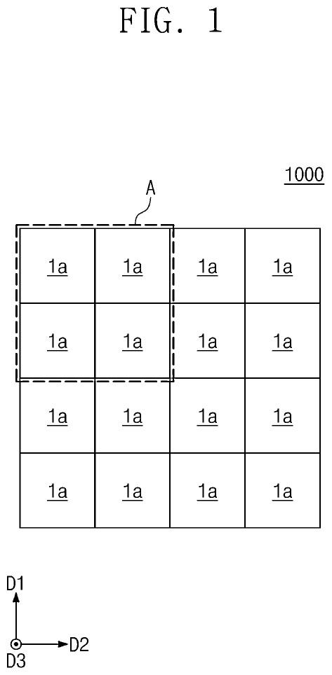

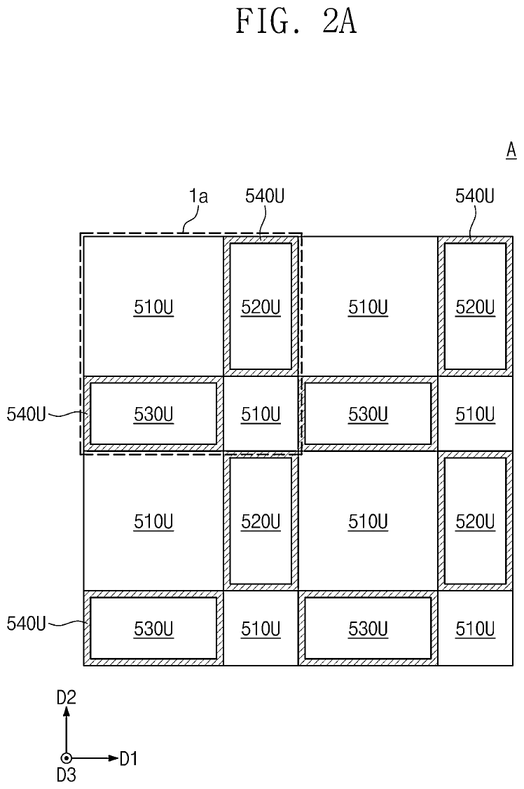

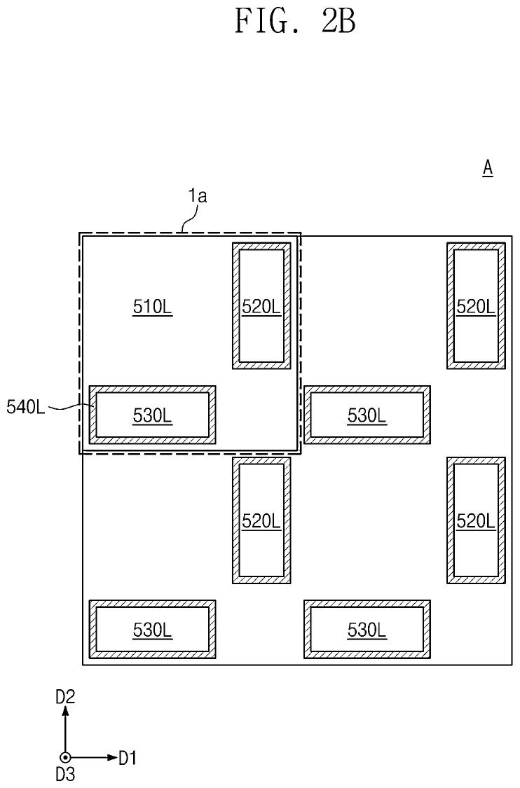

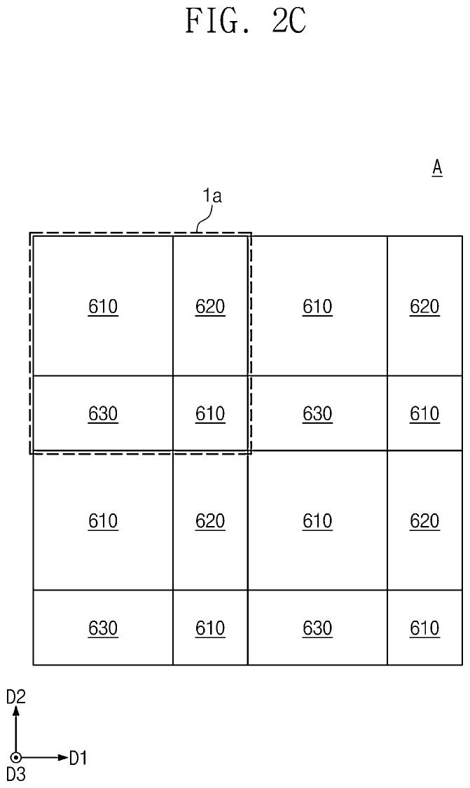

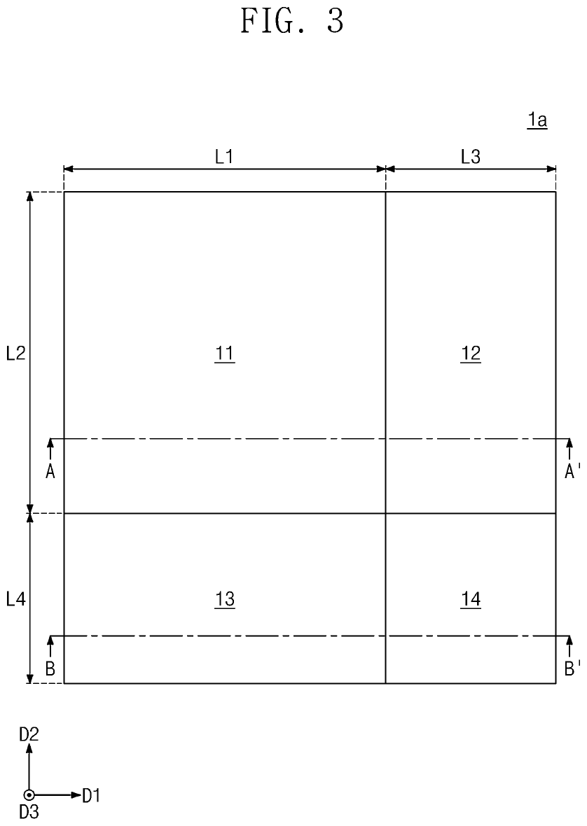

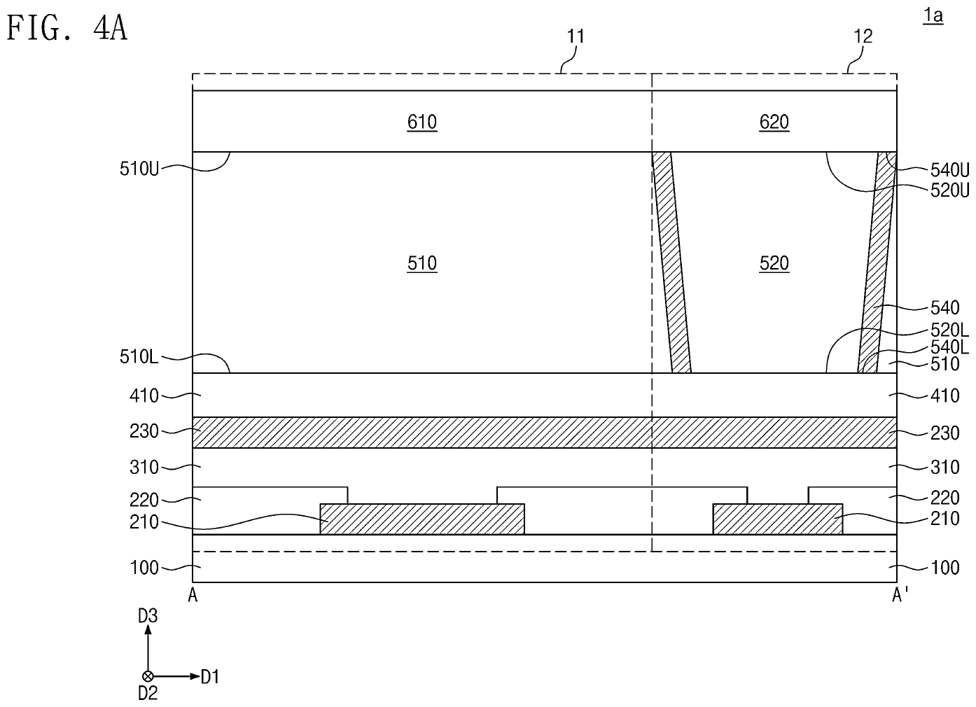

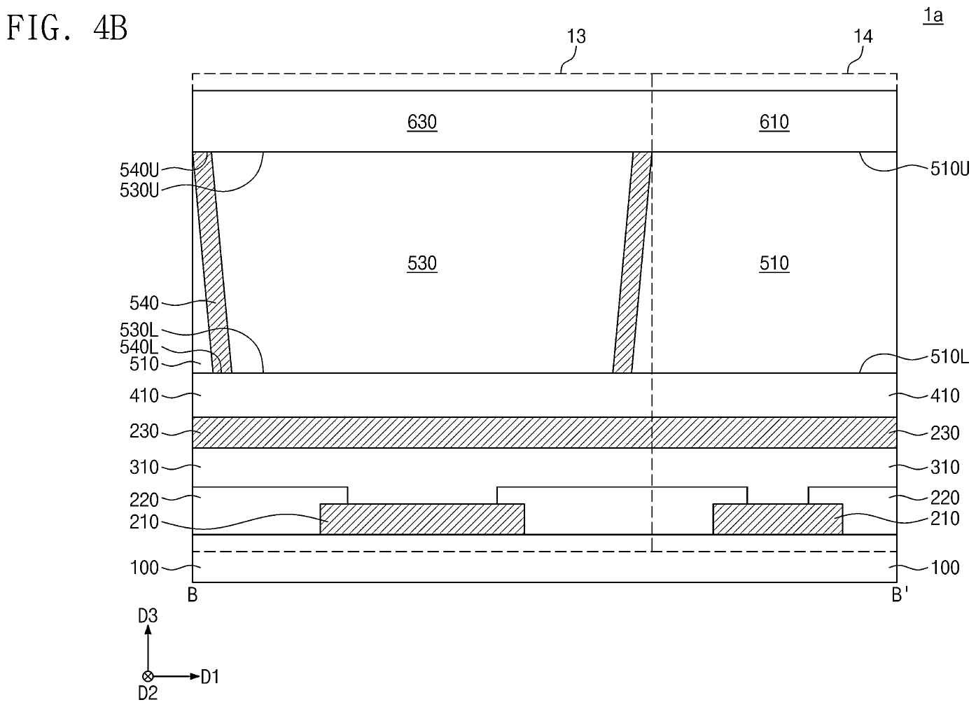

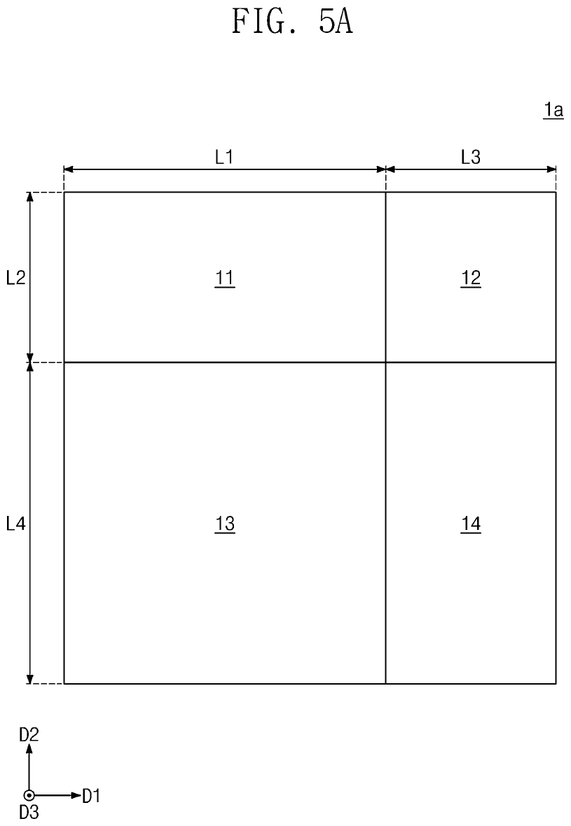

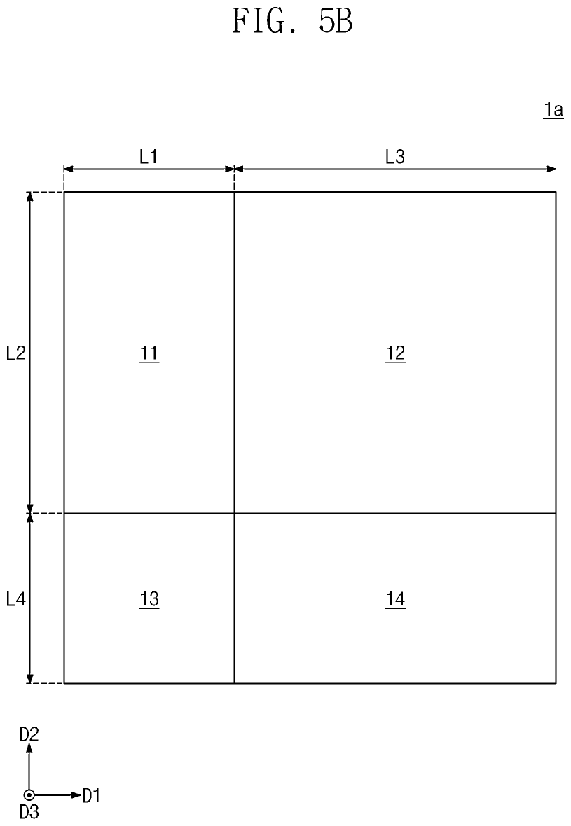

FIG. 1 is a plan view showing a display device according to some embodiments of the inventive concept. FIGS. 2A to 2C are plan views showing region A in FIG. 1. FIG. 3 is a plan view showing a pixel in FIG. 1. FIG. 4A is a cross-sectional view taken along line A-A′ in FIG. 3. FIG. 4B is a cross-sectional view taken along line B-B′ in FIG. 3.

Referring to FIGS. 1 to 4B, a display device 1000 according to some embodiments of the inventive concept may be provided.

The display device 1000 may include a backplane 100 and a pixel 1a on the backplane 100.

The backplane 100 may include silicon and/or glass. The backplane 100 may include a transistor. The backplane 100 may extend in a first direction D1 and a second direction D2 perpendicular to the first direction D1. The backplane 100 may control the brightness of a light source to be described later.

Pixels may be provided on the backplane 100. Referring to FIG. 1, the display device 1000 according to some embodiments of the inventive concept may include a first pixel 1a as a pixel. The first pixel 1a is shown as a square, but is not limited thereto. The first pixel 1a may be provided in plurality.

The first pixel 1a may include sub-pixels 11, 12, 13, and 14. The sub-pixels 11, 12, and 13 may be provided in plurality on the backplane 100. The sub-pixels 11, 12, 13, and 14 may be square in shape on a plane view. Pixels 1 may each include four sub-pixels 11, 12, 13, and 14 disposed in a 2×2 grid pattern.

The first pixel 1a may include one first sub-pixel 11, one second sub-pixel 12, one third sub-pixel 13, and one fourth sub-pixel 14. The first sub-pixel 11 may be a blue sub-pixel. The second sub-pixel 12 may be a green sub-pixel. The third sub-pixel 13 may be a red sub-pixel. The fourth sub-pixel 14 may be a blue sub-pixel and may have substantially the same configuration as the first sub-pixel 11. The fourth sub-pixel 14 may share a driving circuit with the first sub-pixel 11.

The first sub-pixel 11 may be adjacent to both the second sub-pixel 12 and the third sub-pixel 13. The fourth sub-pixel 14 may be adjacent to both the second sub-pixel 12 and the third sub-pixel 13. That is, the first sub-pixel 11 and the fourth sub-pixel 14 may be disposed in a diagonal direction between the first direction D1 and the second direction D2. The arrangement of the sub-pixels 11, 12, 13, and 14 in the first pixel 1a is not limited to FIG. 3, and other embodiments will be described later.

Referring to FIG. 3, on a plane view, the first sub-pixel 11 may have a first length L1 in the first direction D1 and a second length L2 in the second direction D2. The second sub-pixel 12 may have a third length L3 in the first direction D1 and a second length L2 in the second direction D2. The third sub-pixel 13 may have a first length L1 in the first direction D1 and a fourth length L4 in the second direction D2. The fourth sub-pixel 14 may have a third length L3 in the first direction D1 and a fourth length L4 in the second direction D2.

The center point, which is a contact point of boundaries of each sub-pixel 11, 12, 13, and 14, may be provided within the first pixel 1a. For example, for the first pixel 1a, the center point may be located at the center or shifted slightly to the lower right. That is, for example, the first length L1 may be equal to or greater than the third length L3, and the second length L2 may be equal to or greater than the fourth length L4. Pixels that may be included in the display device 1000 are not limited to the first pixel 1a of FIG. 3, and other embodiments will be described later.

The first sub-pixel 11 and the fourth sub-pixel 14 may each include a lower electrode 210, an insulating pattern 220, a first light source 310, an upper electrode 230, an intermediate layer 410, a transparent pattern 510, and a scattering pattern 610.

The second sub-pixel 12 may include a lower electrode 210, an insulating pattern 220, a first light source 310, an upper electrode 230, an intermediate layer 410, a first quantum dot pattern 520, a reflection pattern 540, and a first color filter 620.

The third sub-pixel 13 may include a lower electrode 210, an insulating pattern 220, a first light source 310, an upper electrode 230, an intermediate layer 410, a second quantum dot pattern 530, a reflection pattern 540, and a second color filter 630.

The lower electrode 210 may be provided on the backplane 100. Within the first pixel 1a, the lower electrode 210 may be provided in plurality. The sub-pixels 11, 12, 13, and 14 may each include one lower electrode 210. The lower electrode 210 may serve to reflect light from the first light source 310 upwards. The lower electrode 210 may be, for example, a positive electrode.

The lower electrode 210 may include an electrode material. The electrode material may include a metal, and for example, may include at least one of silver (Ag), aluminum (Al), molybdenum (Mo), cobalt (Co), copper (Cu), gold (Au), platinum (Pt), tungsten (W), chromium (Cr), magnesium (Mg), or lithium (Li), or a combination thereof.

The lower electrode 210 may further include a transparent conductive material. When the lower electrode 210 further includes a transparent conductive material, charge injection properties and light efficiency thereof may be improved. The transparent conductive material may include at least one of transition metal oxide, metal nitride, indium tin oxide, or aluminum-doped zinc oxide, or a combination thereof.

The transition metal oxide may include, for example, at least one of molybdenum oxide (MoO), vanadium oxide (VO), tungsten oxide (WO), nickel oxide (NiO), or rhenium oxide (ReO), or a combination thereof. The metal nitride may include, for example, titanium nitride (TiN).

The lower electrode 210 may further include at least one of a conductive polymer, copper iodide, copper thiocyanate, or a graphene thin film, or a combination thereof. The conductive polymer may include at least one of polypyrrole, polyaniline, polythiophene, or poly-sodium allyloxy hydroxypropyl sulfonate, or a combination thereof.

The insulating pattern 220 may be provided on the backplane 100. The insulating pattern 220 may cover side surfaces of the lower electrodes 210. The insulating pattern 220 may cover a portion of an upper surface of the lower electrode 210. The insulating pattern 220 may be positioned between the lower electrodes 210.

The insulating pattern 220 may include at least one of an inorganic thin film, an organic thin film, or an organic-inorganic composite thin film, or a combination thereof. In a third direction D3 perpendicular to both the first direction D1 and the second direction D2, the insulating pattern 220 may have a thickness of about 10 nm to about 3,000 nm. The insulating pattern 220, as an inorganic thin film, may have a thickness of about 10 nm to about 500 nm in the third direction D3. The insulating pattern 220, as an organic thin film or an organic-inorganic composite thin film, may have a thickness of about 100 nm to about 3,000 nm in the third direction D3.

The inorganic thin film may include, for example, at least one of silicon oxide (SiO), silicon nitride (SiN), silicon oxynitride (SiON), aluminum oxide (AlO), or hafnium oxide (HfO), or a combination thereof, but is not limited thereto. The organic thin film may include, for example, at least one of a poly vinyl chloride (PVC) resin, a vinyl acetate (VA) resin, a polystyrene (PS) resin, a polyamide (PA) resin, a polyimide (PI) resin, a methacrylic acid (MAA) resin, a melamine resin, a polyurethane (PU) resin, a polyethylene resin, an ethylene vinyl copolymer resin, a polypropylene (PP) resin, a polyester resin, an acrylic resin, nylon, a polycarbonate (PC) resin, or cellulose, or a combination thereof, but is not limited thereto. The organic-inorganic composite thin film may include, for example, at least one of hexamethyldisiloxane, polysilazane, polysiloxane, or polysilsesquioxane, or a combination thereof, but is not limited thereto.

The first light source 310 may be provided on the lower electrode 210. The upper electrode 230 may be provided on the first light source 310. The first light source 310 may be a blue light source.

The first light source 310 may include, for example, a hole injection layer, a hole transport layer, a color emitting layer, an electron transport layer, and an electron injection layer. The color emitting layer may be, for example, a blue emitting layer. The first light source 310 may further include a charge generation layer. The lower electrode 210, the first light source 310, and the upper electrode 230 may form a color organic light emitting diode (OLED), and for example, may form a blue organic light emitting diode. The upper electrode 230 may serve to transmit light emitted from the first light source 310.

The electrode material may include a metal, and for example, may include at least one of silver (Ag), aluminum (Al), molybdenum (Mo), cobalt (Co), copper (Cu), gold (Au), platinum (Pt), tungsten (W), chromium (Cr), magnesium (Mg), or lithium (Li), or a combination thereof. The upper electrode 230 may include an electrode material. The upper electrode 230 may be, for example, a negative electrode.

The upper electrode 230 may further include a transparent conductive material. When the upper electrode 230 further includes a transparent conductive material, charge injection properties and light efficiency thereof may be improved. The transparent conductive material may include at least one of transition metal oxide, metal nitride, indium tin oxide, or aluminum-doped zinc oxide, or a combination thereof.

The transition metal oxide may include, for example, at least one of molybdenum oxide (MoO), vanadium oxide (VO), tungsten oxide (WO), nickel oxide (NiO), or rhenium oxide (ReO), or a combination thereof. The metal nitride may include, for example, titanium nitride (TiN).

The upper electrode 230 may further include at least one of a conductive polymer, copper iodide, copper thiocyanate, or a graphene thin film, or a combination thereof. The conductive polymer may include at least one of polypyrrole, polyaniline, polythiophene, or poly-sodium allyloxy hydroxypropyl sulfonate, or a combination thereof.

The intermediate layer 410 may be provided on the upper electrode 230. The intermediate layer 410 may include at least one of an inorganic thin film, an organic thin film, or an organic-inorganic composite thin film, or a combination thereof. The intermediate layer 410 may include a single-layered structure or a multi-layered structure. The inorganic thin film may include, for example, at least one of silicon oxide (SiO), silicon nitride (SiN), silicon oxynitride (SiON), aluminum oxide (AlO), or hafnium oxide (HfO), or a combination thereof, but is not limited thereto. The organic thin film may include, for example, at least one of a poly vinyl chloride (PVC) resin, a vinyl acetate (VA) resin, a polystyrene (PS) resin, a polyamide (PA) resin, a polyimide (PI) resin, a methacrylic acid (MAA) resin, a melamine resin, a polyurethane (PU) resin, a polyethylene resin, an ethylene vinyl copolymer resin, a polypropylene (PP) resin, a polyester resin, an acrylic resin, nylon, a polycarbonate (PC) resin, or cellulose, or a combination thereof, but is not limited thereto. The organic-inorganic composite thin film may include, for example, at least one of hexamethyldisiloxane, polysilazane, polysiloxane, or polysilsesquioxane, or a combination thereof, but is not limited thereto.

The transparent pattern 510 may be provided on the intermediate layer 410. Specifically, the transparent pattern 510 may be provided on the intermediate layer 410 of the first sub-pixel 11 and the fourth sub-pixel 14.

The transparent pattern 510 may be provided in plurality, and multiple transparent patterns 510 may each be in contact with or connected to each other. On a plane view, the transparent patterns 510 may be disposed in a zigzag pattern in a diagonal direction between the first direction D1 and the second direction D2. A width of a lower surface 510L of the transparent pattern 510 in the first direction D1 or the second direction D2 may be equal to or greater than a width of an upper surface 510U. The transparent pattern 510 may have a thickness of about 1 μm to about 20 μm in the third direction D3.

The transparent pattern 510 may be transparent. Accordingly, the transparent pattern 510 may directly emit light of a specific wavelength, emitted from the first light source 310.

The transparent pattern 510 may include at least one of an inorganic thin film, an organic thin film, or an organic-inorganic composite thin film, or a combination thereof. The transparent pattern 510 may include a single-layered structure or a multi-layered structure. The inorganic thin film may include, for example, at least one of silicon oxide (SiO), silicon nitride (SiN), silicon oxynitride (SiON), aluminum oxide (AlO), or hafnium oxide (HfO), or a combination thereof, but is not limited thereto. The organic thin film may include, for example, at least one of a poly vinyl chloride (PVC) resin, a vinyl acetate (VA) resin, a polystyrene (PS) resin, a polyamide (PA) resin, a polyimide (PI) resin, a methacrylic acid (MAA) resin, a melamine resin, a polyurethane (PU) resin, a polyethylene resin, an ethylene vinyl copolymer resin, a polypropylene (PP) resin, a polyester resin, an acrylic resin, nylon, a polycarbonate (PC) resin, or cellulose, or a combination thereof, but is not limited thereto. The organic-inorganic composite thin film may include, for example, at least one of hexamethyldisiloxane, polysilazane, polysiloxane, or polysilsesquioxane, or a combination thereof, but is not limited thereto.

Quantum dot patterns 520 and 530 may be provided on the intermediate layer 410. A plurality of quantum dot patterns 520 and 530 may be provided, and may be spaced apart. Specifically, a first quantum dot pattern 520 may be provided in the second sub-pixel 12, and a second quantum dot pattern 530 may be provided in the third sub-pixel 13. The first quantum dot pattern 520 may be a green quantum dot pattern. The second quantum dot pattern 530 may be a red quantum dot pattern.

The quantum dot patterns 520 and 530 may each be spaced apart from the transparent patterns 510 in the first direction D1 or the second direction D2. on a plane view, the quantum dot patterns 520 and 530 and the transparent pattern 510 may be alternately disposed in the first direction D1 or the second direction D2. On a plane view, the first quantum dot pattern 520 and the second quantum dot pattern 530 may be disposed in a zigzag pattern in a diagonal direction between the first direction D1 and the second direction D2. A width of upper surfaces 520U and 530U of the quantum dot patterns 520 and 530 in the first direction D1 or the second direction D2 may be equal to or greater than a width of lower surfaces 520L and 530L.

The first quantum dot pattern 520 and the second quantum dot pattern 530 may each include a quantum dot. The quantum dot included in the first quantum dot pattern 520 may convert a wavelength of light emitted from the first light source 310 into a wavelength of green light. The quantum dot included in the second quantum dot pattern 530 may convert a wavelength of light emitted from the first light source 310 into a wavelength of red light. The color to which the quantum dot converts the wavelength of light emitted from the first light source 310 may vary depending on the size of the quantum dot.

The quantum dot may include at least one of a Group II-VI compound, a Group III-V compound, a Group IV-VI compound, a Group I-III-VI compound, a Group IV element, or a Group IV compound, or a combination thereof.

The Group II-VI compound may include at least one of a Group II-VI binary compound, a Group II-VI ternary compound, or a Group II-VI quaternary compound, or a combination thereof. The Group II-VI binary compound may include at least one of CdSe, CdTe, ZnS, ZnSe, ZnTe, HgS, HgSe, HgTe, MgSe, or MgS, or a combination thereof. The Group II-VI ternary compound may include at least one of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS, or a combination thereof. The Group II-VI quaternary compound may include at least one of HgZnTeS, CdZnSeS, CdZnSeTe, CdZnSTe, CdHgSeS, CdHgSeTe, CdHgSTe, HgZnSeS, HgZnSeTe, or HgZnSTe, or a combination thereof.

The Group III-V compound may include at least one of a Group III-V binary compound, a Group III-V ternary compound, or a Group III-V quaternary compound, or a combination thereof. The Group III-V binary compound may include at least one of GaN, GaP, GaAs, GaSb, AlN, AlP, AlAs, AlSb, InN, InP, InAs, or InSb, or a combination thereof. The Group III-V ternary compound may include at least one of GaNP, GaNAs, GaNSb, GaPAs, GaPSb, AlNP, AlNAs, AlNSb, AlPAs, AlPSb, InGaP, InNP, InNAs, InNSb, InPAs, InPSb, or GaAlNP, or a combination thereof. The III-V group quaternary compound may include at least one of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, or InAlPSb, or a combination thereof.

The Group IV-VI compound may include at least one of a Group IV-VI binary compound, a Group IV-VI ternary compound, or a Group IV-VI quaternary compound, or a combination thereof. The Group IV-VI binary compound may include at least one of SnS, SnSe, SnTe, PbS, PbSe, or PbTe, or a combination thereof. The Group IV-VI ternary compound may include at least one of SnSeS, SnSeTe, SnSTe, PbSeS, PbSeTe, PbSTe, SnPbS, SnPbSe, or SnPbTe, or a combination thereof. The Group IV-VI quaternary compound may include at least one of SnPbSSe, SnPbSeTe, or SnPbSTe, or a combination thereof.

The Group I-III-VI compound may include at least one of a Group I-III-VI ternary compound, or a Group I-III-VI quaternary compound, or a combination thereof. The Group I-III-VI ternary compound may include at least one of AgInS, AgInSe, AgInTe, CuInS, CuInSe, or CuInTe, or a combination thereof. The Group I-III-VI quaternary compound may include at least one of AgInSeS, AgInSeTe, AgInGaS, AgInGaSe, CuInSeS, CuInSeTe, CuInGaS, or CuInGaSe, or a combination thereof.

The Group IV element may include at least one of C, Si, or Ge, or a combination thereof. The Group IV compound may include at least one of SiC, or SiGe, or a combination thereof.

The quantum dot may include a core, and the core may include at least one of the compounds described above, i.e., the Group II-VI compound, the Group III-V compound, the Group IV-VI compound, the Group I-III-VI compound, the Group IV element, or the Group IV compound, or a combination thereof. The quantum dot may further include, for example, a shell.

The reflection pattern 540 may be provided on the intermediate layer 410. The reflection pattern 540 may be positioned between the transparent pattern 510 and the quantum dot patterns 520 and 530. The reflection pattern 540 may cover a side surface of the transparent pattern 510. The reflection pattern 540 may cover a side surface of the quantum dot patterns 520 and 530.

The reflection pattern 540 may include at least one of a metal element, a metal alloy, a transition metal oxide, a metal nitride, or an inorganic thin film, or a combination thereof. The metal element may include, for example, at least one of Ag, Al, Mo, Co, W, Ti, Cu, Ta, Ni, Pt, Nb, Cr, Mg, Li, Sc, Ce, Gd, Sm, V, or Fe, or combinations thereof. The metal alloy may include, for example, at least one of Al/Cr, Al/Co, Al/Cu, Al/Mg, Al/Ni, Al/Sc, Al/Si/Cu, Al/Si, Al/Ti, Al/Ce, Ce/Gd, Ce/Sm, Co/Ni/Cr, Cu/Ge, Cu/In, Cu/Zn, Fe/Mn, Mn/Cu, Mn/Ni, Ni/Cr/Al, Si/Cr/Si, Ni/Zr, Sc/Al, Sn/Zn, Ti/Al/V, or Zn/Sn, or a combination thereof. The transition metal oxide may include, for example, at least one of molybdenum oxide (MoOx), vanadium oxide (VOx), tungsten oxide (WOx), nickel oxide (NiOx), or rhenium oxide (ReOx), or a combination thereof. The metal nitride may include, for example, titanium nitride (TiN). The inorganic thin film may include, for example, at least one of silicon oxide (SiOx), silicon nitride (SiNx), silicon oxynitride (SiOxNy), aluminum oxide (AlOx), hafnium oxide (HfOx), or hexamethyldisiloxane, or a combination thereof.

The scattering pattern 610 may be provided on the transparent pattern 510. A plurality of scattering patterns 610 may be provided within the first pixel 1a. Specifically, the scattering patterns 610 may be provided on the transparent patterns 510 of the first sub-pixel 11 and the fourth sub-pixel 14. That is, the scattering patterns 610 may be disposed in a zigzag pattern in a diagonal direction between the first direction D1 and the second direction D2.

The scattering pattern 610 may include a scattering agent. The scattering agent may include at least one of titanium oxide (TiO₂), zinc oxide (ZnO), tin oxide (SnO), silicon oxide (SiO), nickel oxide (NiO), magnesium oxide (MgO), zirconium oxide (ZrO₂), barium titanate (BaTiO₃), silicon carbide (SiC), boron nitride (BN), aluminum nitride (AlN), gallium nitride (GaN), zinc sulfide (ZnS), copper chloride (CuCl), strontium titanate (SrTiO₃), or lithium niobate (LiNbO₃), or a combination thereof. The scattering agent may include particles of the above-described compounds, and the particles may have a diameter of about 10 nm to about 700 nm, or about 100 nm to about 300 nm. The scattering pattern 610 may alter the distribution of backlight emitted from the first light source 310, and ultimately increase light extraction efficiency to improve the luminance of the display device 1000.

The color filters 620 and 630 may be provided on the quantum dot patterns 520 and 530. Specifically, the first color filter 620 may be provided on the first quantum dot pattern 520 of the second sub-pixel 12, and the second color filter 630 may be provided on the second quantum dot pattern 530 of the third sub-pixel 13. The first color filter 620 may be a green color filter. That is, the first color filter 620 may selectively transmit green light. The second color filter 630 may be a red color filter. That is, the second color filter 630 may selectively transmit red light. The first color filter 620 and the second color filter 630 may absorb undesired light that is not absorbed by the first quantum dot pattern 520 and the second quantum dot pattern 530, and thus improve the color reproducibility of the display device 1000.

Hereinafter, a description will be given of pixels having different configurations that may be included in the display device 1000 according to some embodiments of the inventive concept.

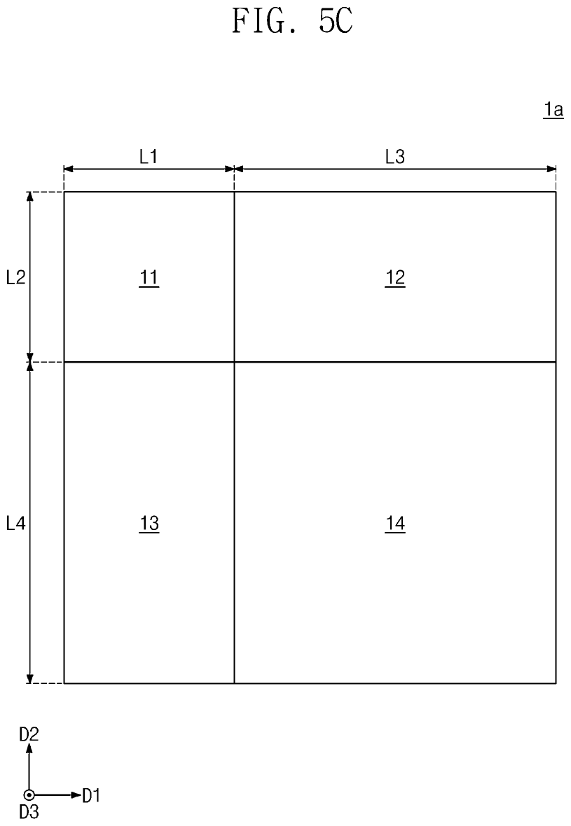

FIGS. 5A to 5C are plan views showing pixels that may be included in a display device according to some embodiments of the inventive concept.

A first pixel 1a of FIG. 5A includes sub-pixels 11, 12, 13, and 14 that are identical to the sub-pixels 11, 12, 13, and 14 included in the first pixel 1a of FIGS. 1 and 3, but a second length L2 may be smaller than a fourth length L4.

A first pixel 1a of FIG. 5B includes sub-pixels 11, 12, 13, and 14 that are identical to the sub-pixels 11, 12, 13, and 14 included in the first pixel 1a of FIGS. 1 and 3, but a first length L1 may be smaller than a third length L3.

A first pixel 1a of FIG. 5C includes sub-pixels 11, 12, 13, and 14 that are identical to the sub-pixels 11, 12, 13, and 14 included in the first pixel 1a of FIGS. 1 and 3, but a first length L1 may be smaller than a third length L3, and a second length L2 may be smaller than a fourth length L4.

The center point may vary depending on the luminous efficiency of a first light source 310 and the luminous efficiency of a quantum dot pattern 520. A size relationship between the first length L1 and the third length L3 and a size relationship between the second length L2 and the fourth length L4 may be independent.

The display device 1000 according to an embodiment of the inventive concept may have high color reproducibility by preventing color mixing of light through a reflection pattern 540 positioned between a transparent pattern 510 and quantum dot patterns 520 and 530. Color filters 620 and 630 may be provided on the quantum dot patterns 520 and 530 to help achieve high color reproducibility. A plurality of transparent patterns 510 are provided in a zigzag pattern diagonally between the first direction D1 and the second direction D2, and may thus increase process convenience. In addition, high light efficiency may be achieved by controlling the lengths L1, L2, L3, and L4 of the sub-pixels 11, 12, 13, and 14 in the first direction D1 and/or the second direction D2 according to the luminous efficiency of the first light source 310 and the light conversion efficiency of the quantum dot patterns 520 and 530.

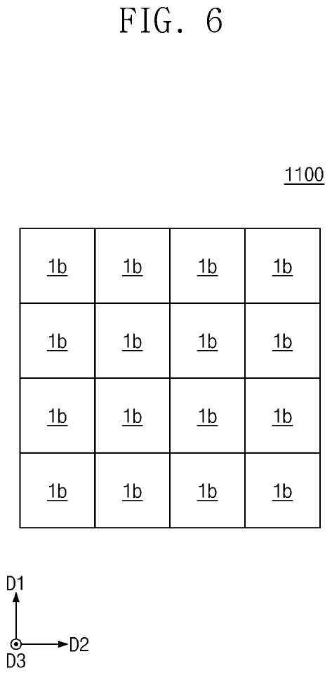

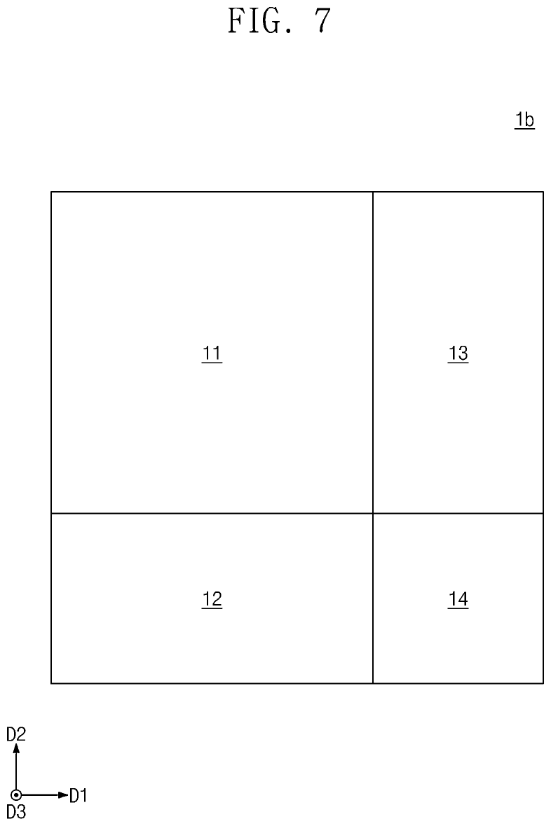

FIG. 6 is a plan view showing a display device according to some embodiments of the inventive concept. FIG. 7 is a plan view showing a pixel in FIG. 6.

Referring to FIGS. 6 and 7, a display device 1100 according to some embodiments of the inventive concept may be provided. The display device 1100 may include a plurality of second pixels 1b.

The second pixel 1b may include sub-pixels 11, 12, 13, and 14 that are identical to those of the first pixel 1a. In the second pixel 1b, the arrangement of the sub-pixels may be different from that of the first pixel 1a. Referring to FIG. 7, the first sub-pixel 11 and the second sub-pixel 12 may be positioned adjacent in the second direction D2, and the first sub-pixel 11 and the third sub-pixel 13 may be positioned adjacent in the first direction D1.

### [Method for Manufacturing a Display Device]

Hereinafter, a method for manufacturing a display device according to some embodiments of the inventive concept will be described.

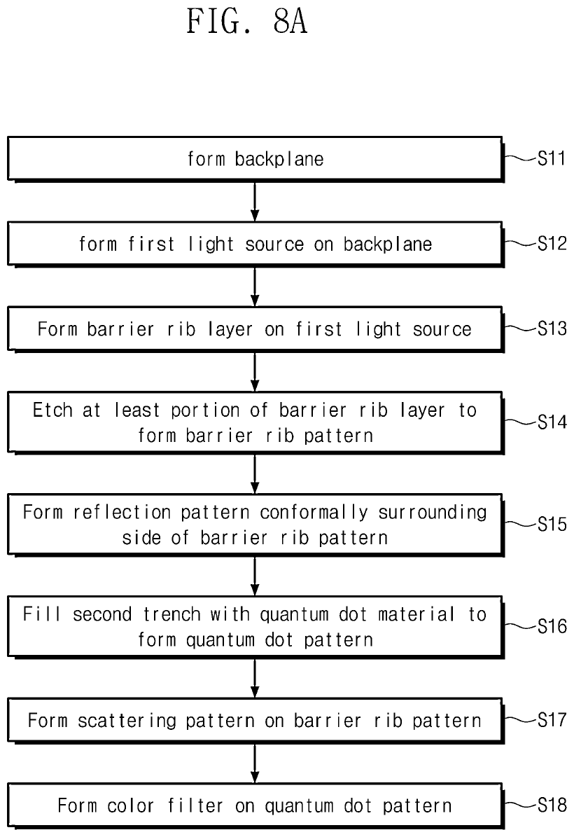

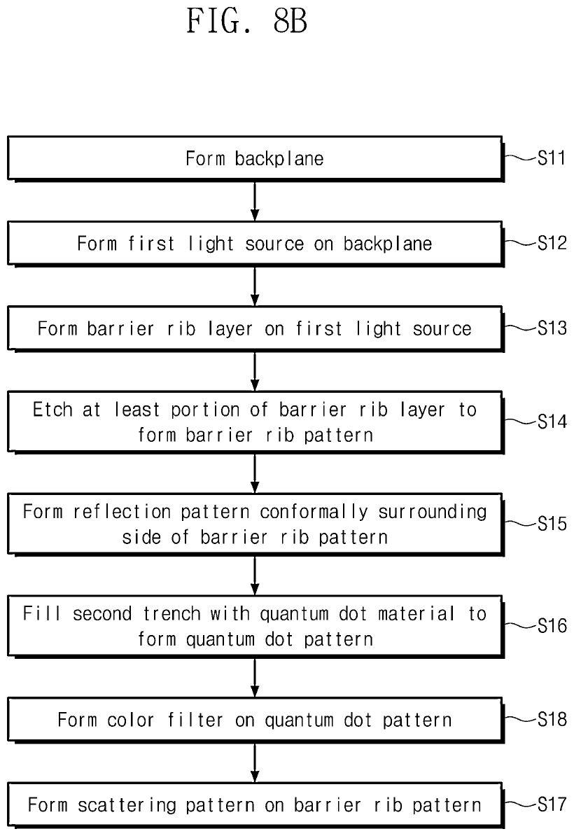

FIG. 8A shows a method for manufacturing a display device according to some embodiments of the inventive concept in FIG. 1.

A method for manufacturing display devices 1000 according to some embodiments of the inventive concept may include forming a backplane 100 (S11), forming a first light source 310 on the backplane 100 (S12), forming a barrier rib layer (not shown) on the first light source 310 (S13), etching at least a portion of the barrier rib layer (not shown) to form a transparent pattern 510 (S14), forming a first trench T1 through the forming of the transparent pattern 510, and forming a reflection pattern 540 surrounding a side surface of the transparent pattern 510 (S15), forming a second trench T2 through the forming of the reflection pattern 540, and filling the second trench T2 with a quantum dot material to form quantum dot patterns 520 and 530 (S16), forming a scattering pattern 610 on the transparent pattern 510 (S17), and forming color filters 620 and 630 on the quantum dot patterns 520 and 530 (S18).

FIG. 8B shows a method for manufacturing a display device according to some embodiments of the inventive concept in FIG. 1.

Referring to FIG. 8B along with FIG. 8A, the forming of the scattering pattern 610 on the transparent pattern 510 (S17) and the forming of the color filters 620 and 630 on the quantum dot patterns 520 and 530 (S18) may be performed regardless of temporal antecedent order. That is, the color filters 620 and 630 may be formed after the forming of the scattering pattern 610 as in FIG. 6A, or the scattering pattern 610 may be formed after the forming of the color filters 620 and 630 as in FIG. 6B.

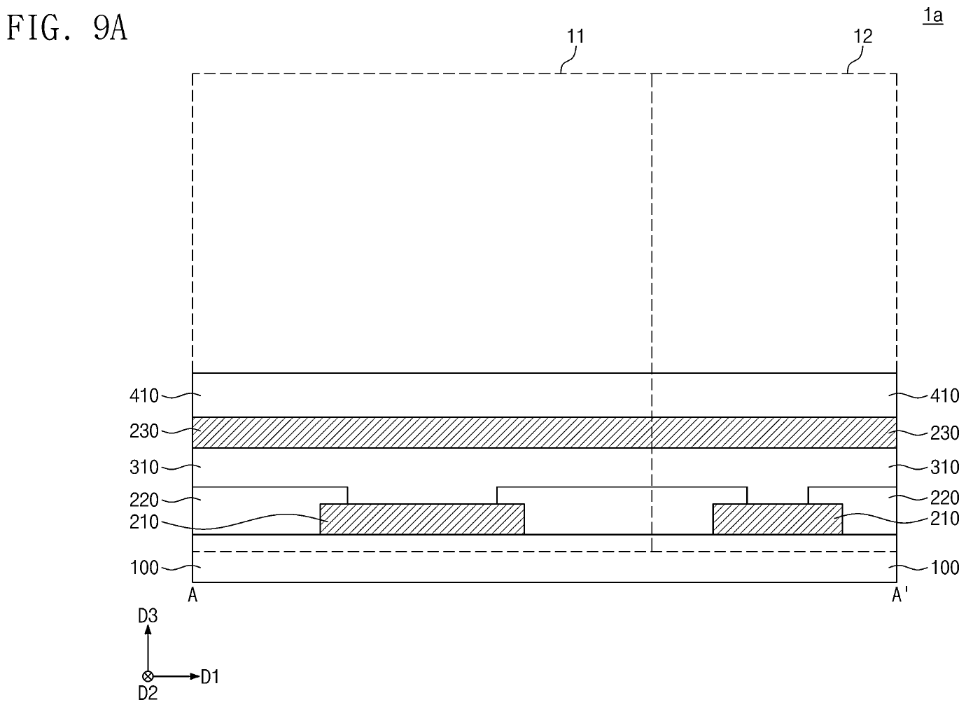

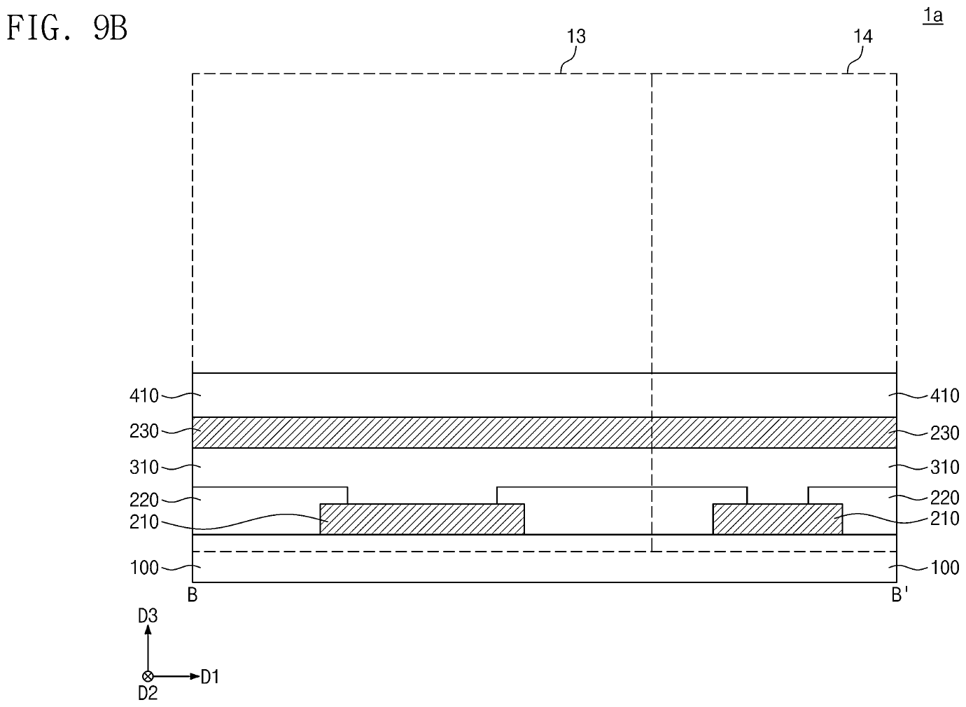

FIGS. 9A to 13B show a method for manufacturing a display device according to some embodiments of the inventive concept in FIG. 1.

Referring to FIGS. 9A and 9B, a backplane 100 may be formed. The backplane 100 may be formed by a complementary metal oxide semiconductor (CMOS) process and/or a thin film transistor (TFT) process.

A lower electrode 210 may be provided on the backplane 100. The lower electrode 210 may be formed through a sputtering process, a thermal deposition process, a chemical vapor deposition (CVD) process, an atomic layer deposition (ALD) process, a spin coating process, a bar coating process, a blade coating process, plating, a slit coating process, a slot die coating process, and/or a printing process.

An insulating pattern 220 may be formed on the backplane 100. The insulating pattern 220 may be positioned between the lower electrodes 210. The forming of the insulating pattern 220 may include, for example, forming an insulating layer (not shown) and selectively etching the insulating layer (not shown).

A first light source 310 may be formed on the lower electrode 210. The forming of the first light source 310 may include sequentially forming a hole injection layer, a hole transport layer, a color emitting layer, an electron transport layer, and an electron injection layer. The first light source 310 may be formed, for example, through a thermal deposition process.

An upper electrode 230 may be formed on the first light source 310. The upper electrode 230 may be formed through a sputtering process, a thermal deposition process, a chemical vapor deposition (CVD) process, an atomic layer deposition (ALD) process, a spin coating process, a bar coating process, a blade coating process, plating, a slit coating process, a slot die coating process, and/or a printing process.

An intermediate layer 410 may be formed on the upper electrode 230. The forming of the intermediate layer 410 may include depositing at least any one material from the group consisting of the inorganic thin film, the organic thin film, and the organic-inorganic composite thin film, which are described above.

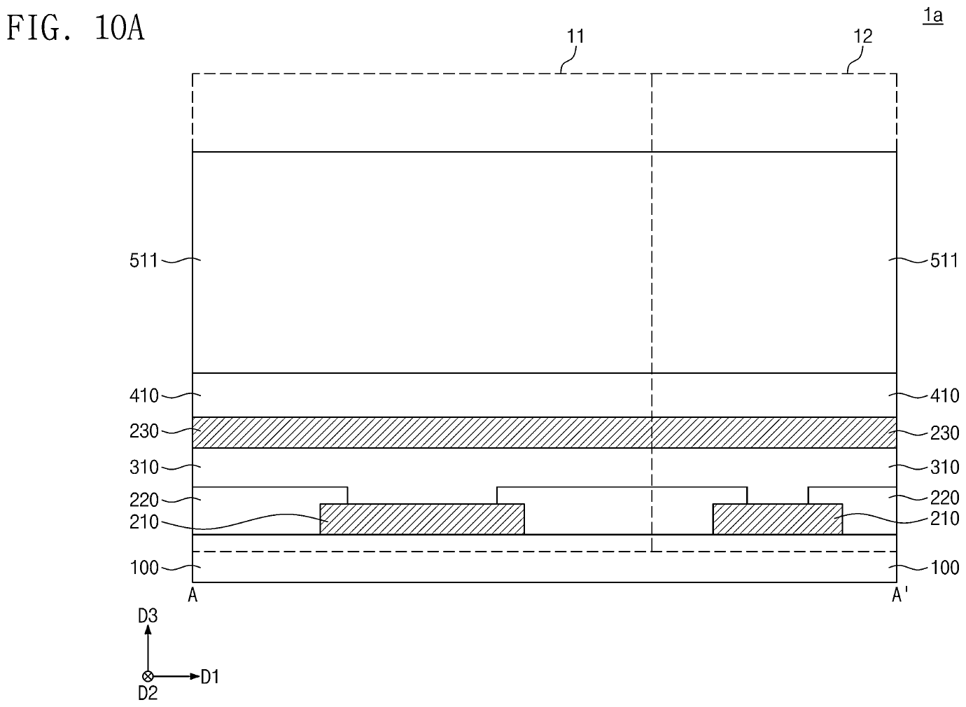

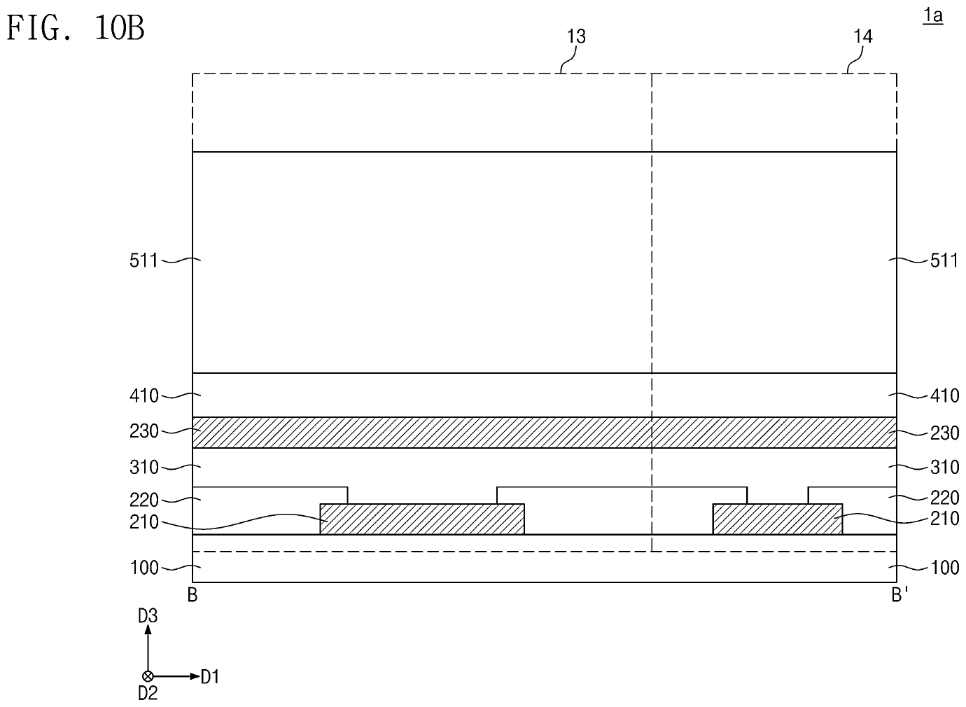

Referring to FIGS. 10A and 10B, a barrier rib layer 511 may be formed on the intermediate layer 410. The barrier rib layer 511 may cover an upper surface of the intermediate layer 410. The forming of the barrier rib layer 511 may include depositing at least any one material from the group consisting of the inorganic thin film, the organic thin film, and the organic-inorganic composite thin film, which are described above.

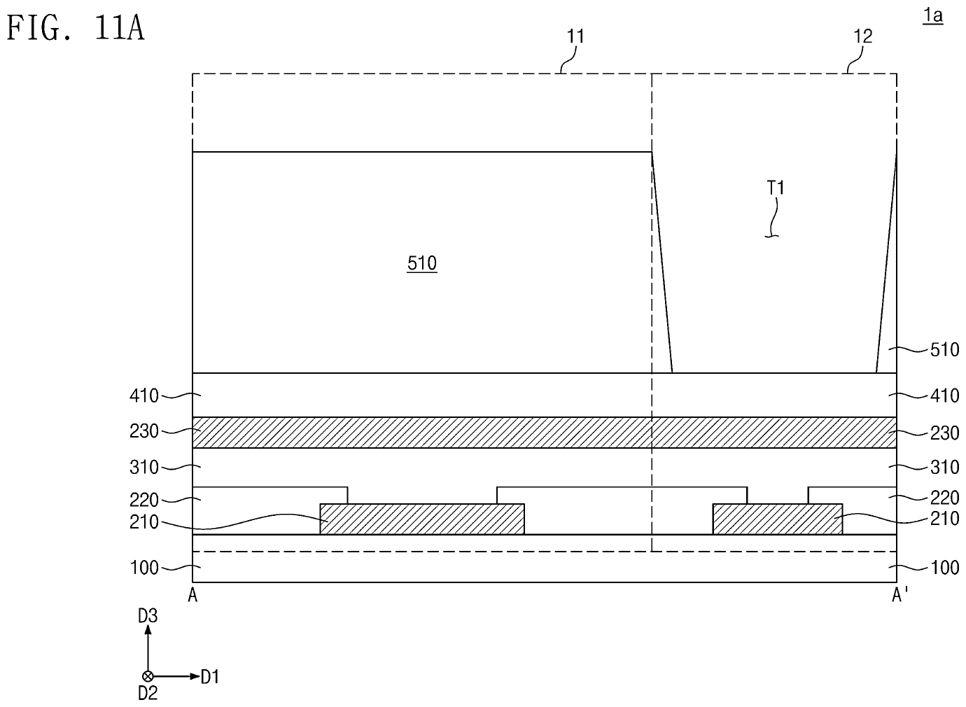

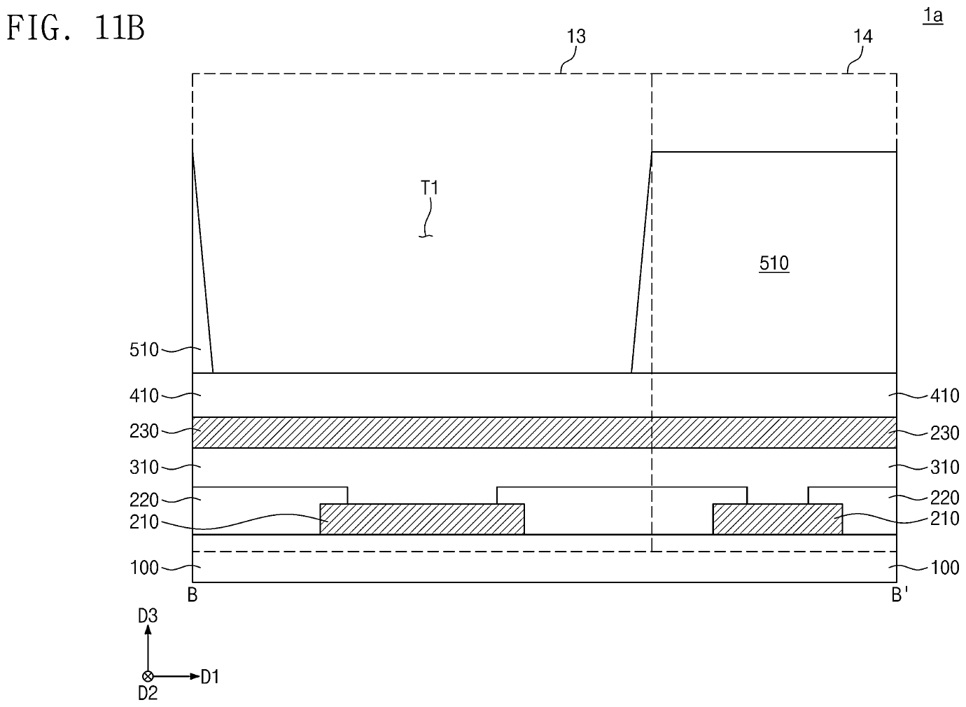

Referring to FIGS. 11A and 11B, at least a portion of the barrier rib layer 511 may be removed to form a transparent pattern 510.

The transparent pattern 510 may be provided in plurality. A first trench T1 may be formed between the transparent patterns 510. The first trench T1 may expose an upper surface of the intermediate layer 410. When being closer to the backplane 100, a width of the first trench T1 in the first direction D1 or the second direction D2 may remain constant or decrease.

The removing of at least a portion of the barrier rib layer 511 may include, for example, etching a portion of the barrier rib layer 511 and/or developing a portion of the barrier rib layer 511.

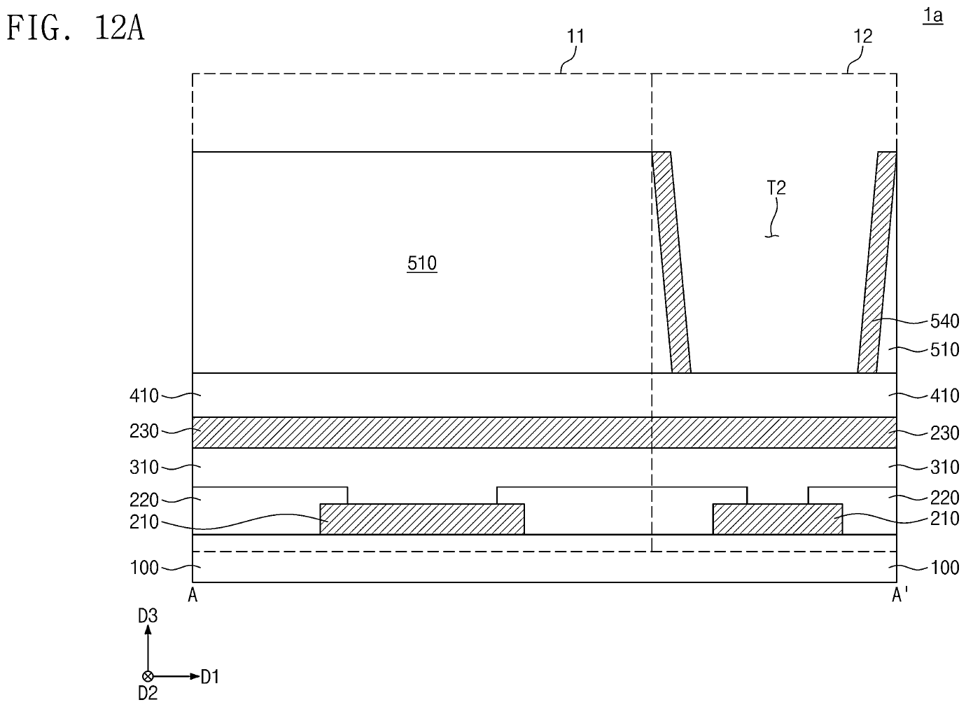

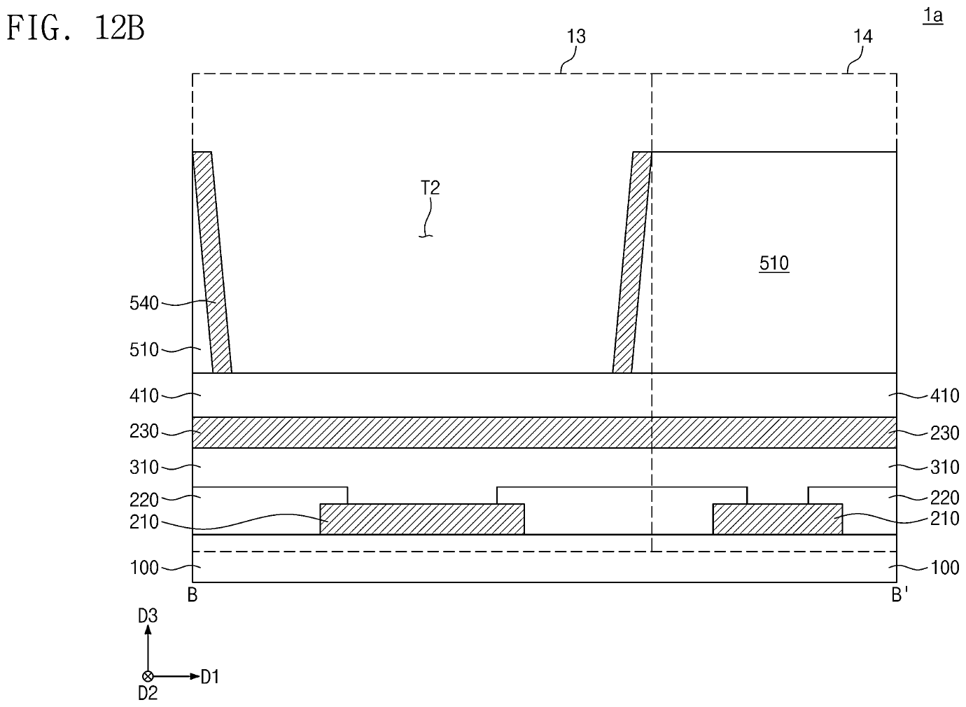

Referring to FIGS. 12A and 12B, a reflection pattern 540 may be formed on a side surface of the transparent pattern 510. The reflection pattern 540 may cover a side surface of the transparent pattern 510.

A second trench T2 may be formed through the forming of the reflection pattern 540. The second trench T2 may expose an upper surface of the intermediate layer 410. The second trench T2 may be positioned between the transparent patterns 510 that are spaced apart, and may be positioned between the reflection patterns 540 that are spaced apart. A width of the second trench T2 may be equal to or smaller than a width of the first trench T1. When being closer to the backplane 100, a width of the second trench T2 in the first direction D1 or the second direction D2 may remain constant or decrease.

The forming of the reflection pattern 540 may include, for example, forming a reflection layer (not shown) on an upper surface of the transparent pattern 510, a side surface of the transparent pattern 510, and an upper surface of the intermediate layer 410, and etching the reflection layer (not shown) formed on the upper surface of the transparent pattern 510 and the upper surface of the intermediate layer 410.

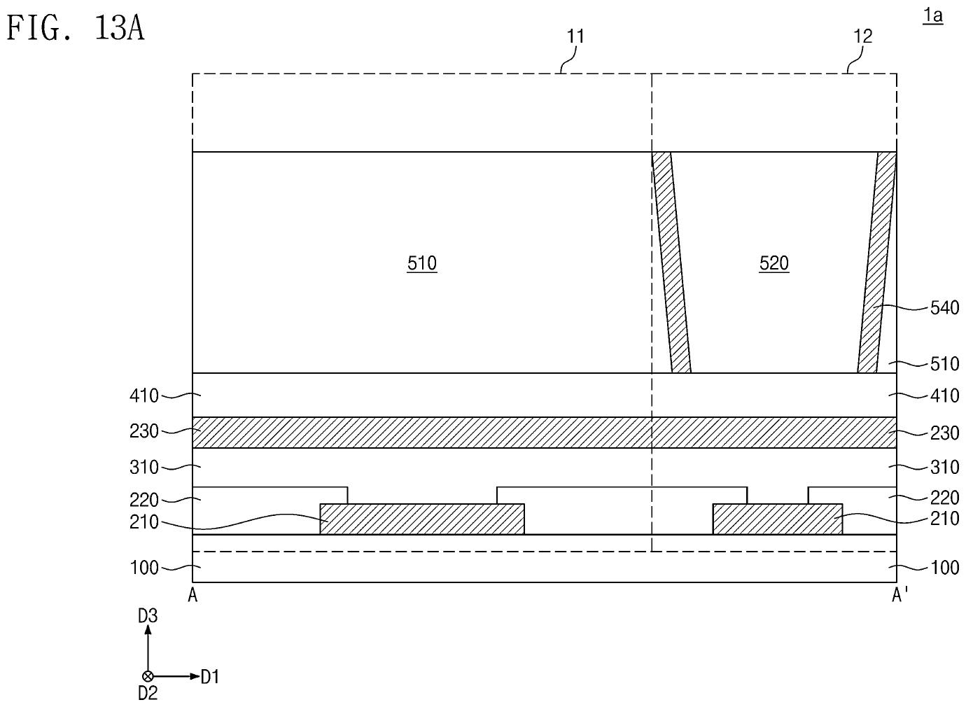

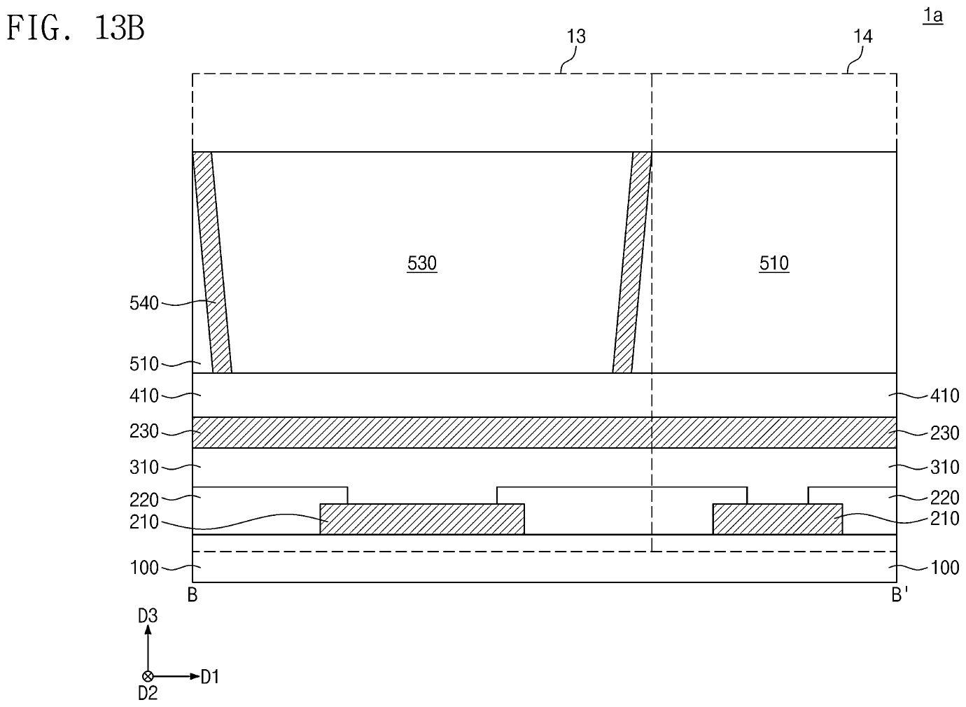

Referring to FIGS. 13A and 13B, a first quantum dot pattern 520 may be formed on the intermediate layer 410 of the second sub-pixel 12. A second quantum dot pattern 530 may be formed on the intermediate layer 410 of the third sub-pixel 13. The forming of the first quantum dot pattern 520 and the forming of the second quantum dot pattern 530 may be performed regardless of temporal antecedent order.

The forming of the first quantum dot pattern 520 may include, for example, selectively filling the second trench T2 of the second sub-pixel 12 with a quantum dot material. The selective filling of the second trench T2 of the second sub-pixel 12 with a quantum dot material may be performed, for example, through a photolithography process. The forming of the second quantum dot pattern 530 may include, for example, selectively filling the second trench T2 of the third sub-pixel 13 with a quantum dot material. The selective filling of the second trench T2 of the third sub-pixel 13 with a quantum dot material may be performed, for example, through a photolithography process.

The quantum dot material may include a quantum dot. The description of the quantum dot is the same as described above.

Referring back to FIGS. 4A and 4B, a scattering pattern 610 may be formed on the transparent pattern 510. A first color filter 620 may be formed on the first quantum dot pattern 520. A second color filter 630 may be formed on the second quantum dot pattern 530. The forming of the scattering pattern 610, the first color filter 620, and the second color filter 630 may be performed regardless of temporal antecedent order.

The forming of the scattering pattern 610 may be, for example, selectively depositing the scattering pattern 610 on the transparent pattern 510. The forming of the first color filter 620 may include, for example, selectively depositing the first color filter 620 on the first quantum dot pattern 520. The forming of the second color filter 630 may include, for example, selectively depositing the second color filter 630 on the second quantum dot pattern 530. The forming of the scattering pattern 610, the forming of the first color filter 620, and the forming of the second color filter 630 may be performed, for example, through a photolithography process.

The method for manufacturing the display devices 1000 and 1100 according to an embodiment of the inventive concept may involve forming the transparent patterns 510 disposed in a zigzag pattern in a diagonal direction between the first direction D1 and the second direction D2, and then forming the reflection pattern 540, thereby preventing color mixing of light and achieving high color reproducibility.

### [Display Device]

Hereinafter, a display device according to other embodiments of the inventive concept is described.

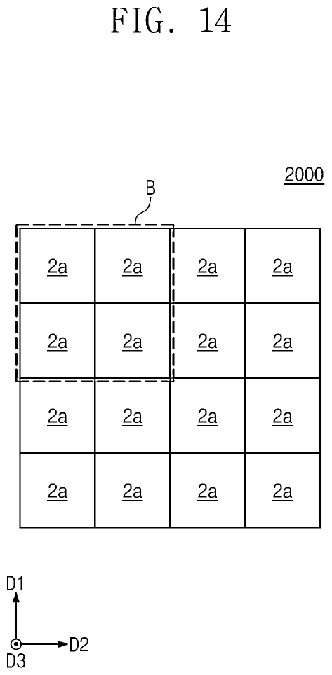

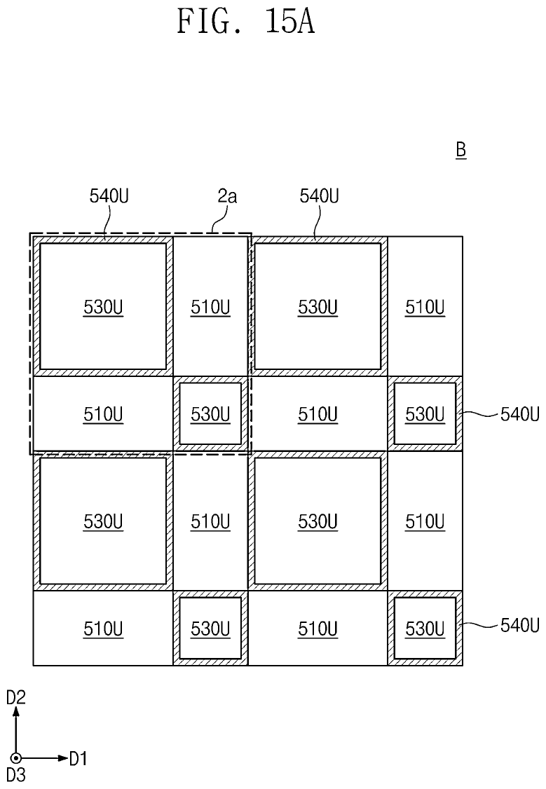

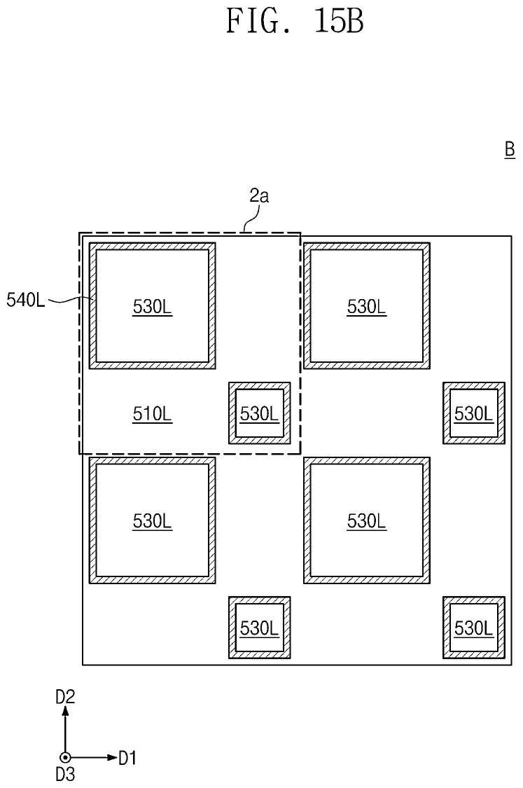

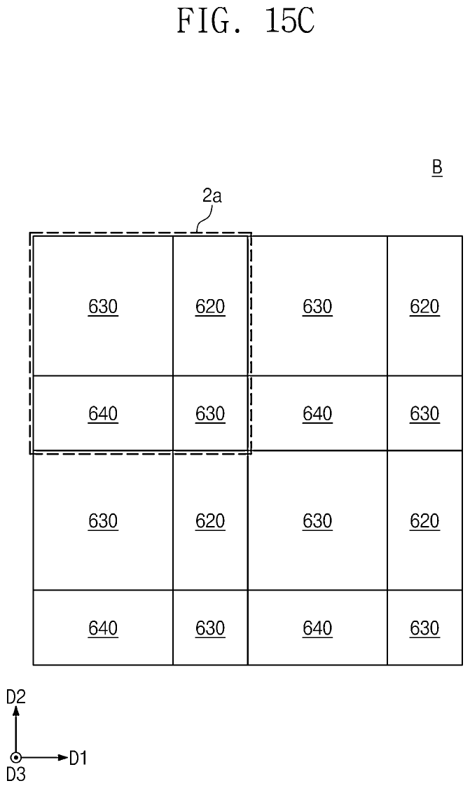

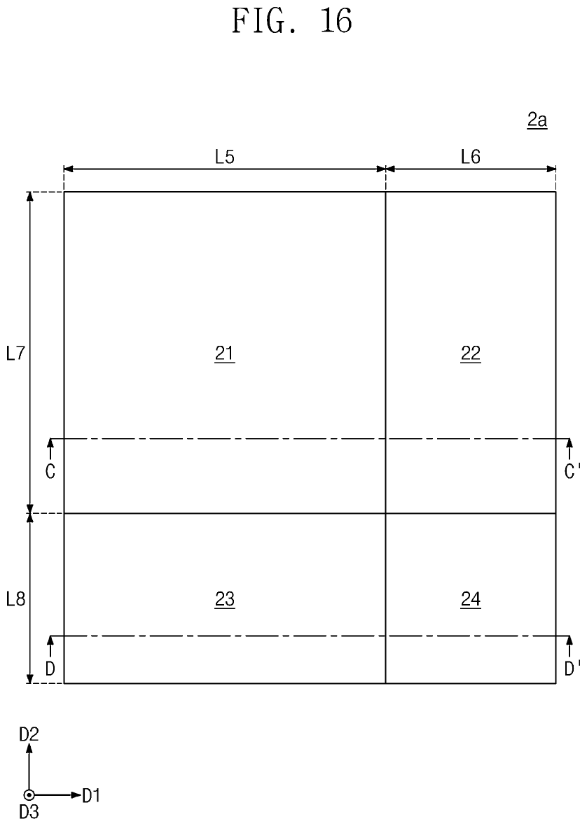

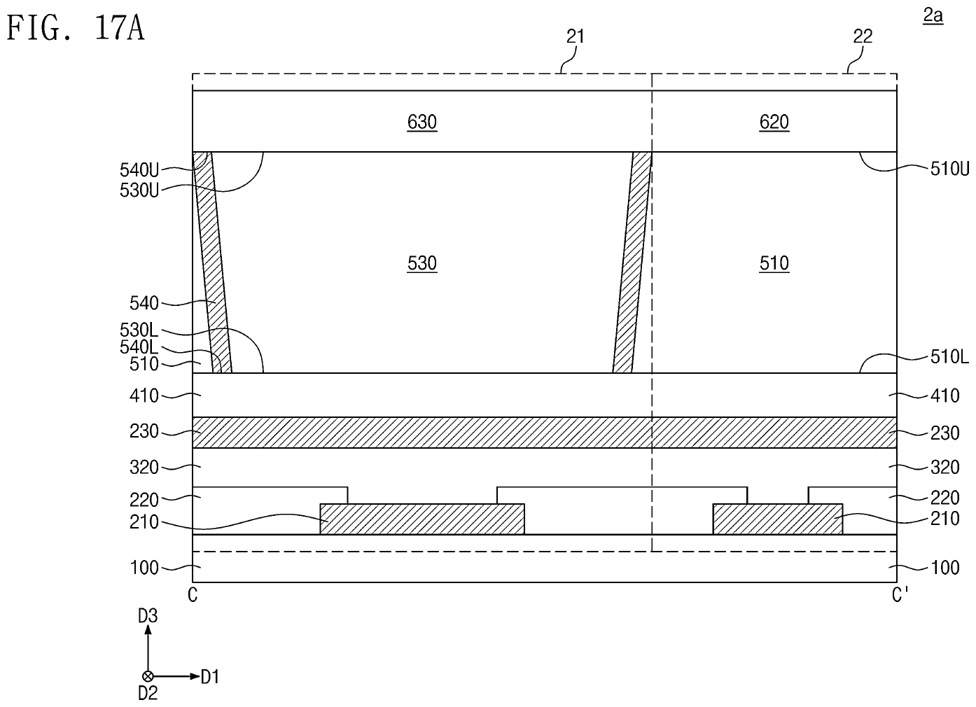

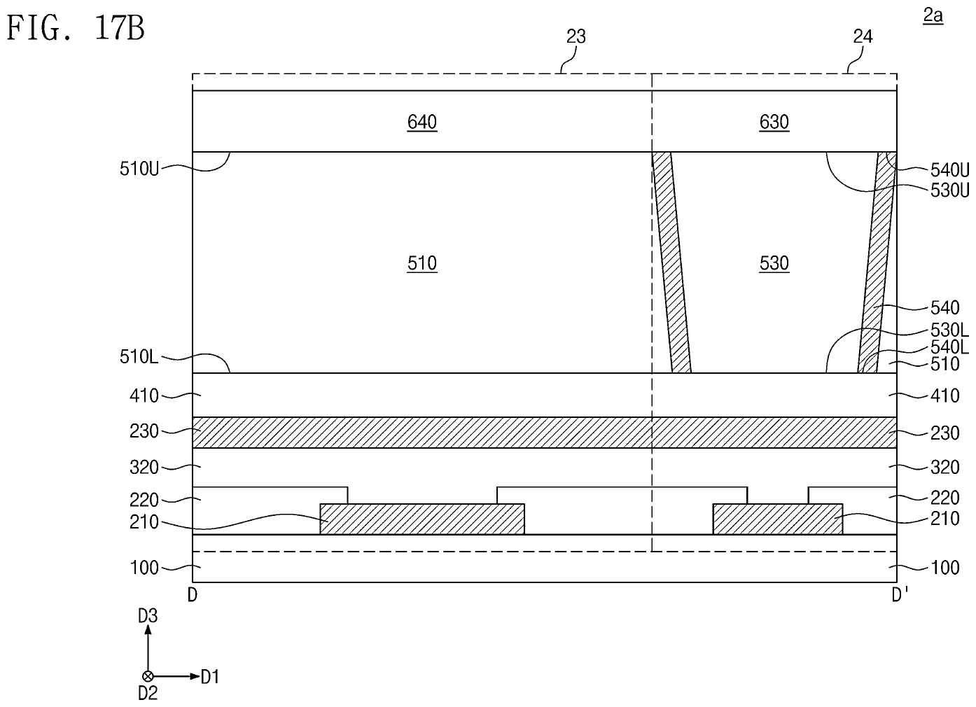

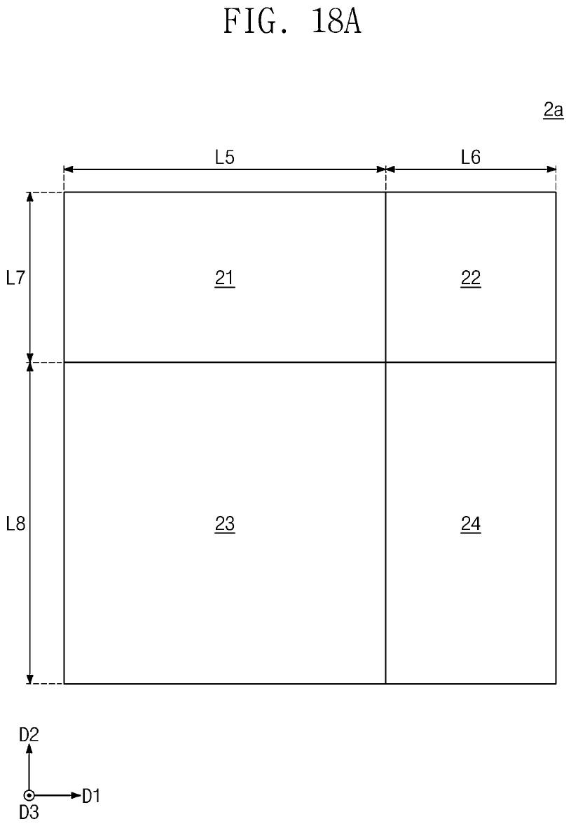

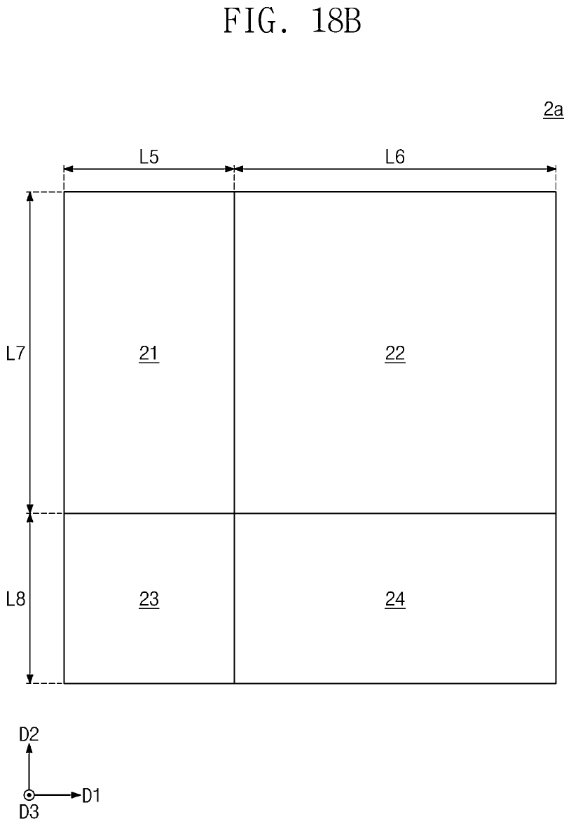

FIG. 14 is a plan view showing a display device according to some embodiments of the inventive concept. FIGS. 15A to 15C are plan views showing region B in FIG. 14. FIG. 16 is a plan view showing a pixel in FIG. 14. FIG. 17A is a cross-sectional view taken along line A-A′ in FIG. 16. FIG. 17B is a cross-sectional view taken along line B-B′ in FIG. 16.

Referring to FIGS. 14 to 17B, a display device 2000 according to some embodiments of the inventive concept may be provided.

The display device 2000 may include a backplane 100 and a pixel 2a on the backplane 100.

Pixels may be provided on the backplane 100. Referring to FIG. 14, the display device 2000 according to some embodiments of the inventive concept may include a third pixel 2a as a pixel. The third pixel 2a may include four sub-pixels 11, 12, 13, and 14 disposed in a 2×2 grid pattern.

The third pixel 2a may include one fifth sub-pixel 21, one sixth sub-pixel 22, one seventh sub-pixel 23, and one eighth sub-pixel 24. The fifth sub-pixel 21 may be a red sub-pixel. The sixth sub-pixel 22 may be a green sub-pixel. The seventh sub-pixel 23 may be a blue sub-pixel. The eighth sub-pixel 24 may be a red sub-pixel and may have substantially the same configuration as the fifth sub-pixel 21. The eighth sub-pixel 24 may share a driving circuit with the fifth sub-pixel 21.

The fifth sub-pixel 21 may be positioned adjacent to both the sixth sub-pixel 22 and the seventh sub-pixel 23. The eighth sub-pixel 24 may be positioned adjacent to both the sixth sub-pixel 22 and the seventh sub-pixel 23. That is, the fifth sub-pixel 21 and the eighth sub-pixel 24 may be disposed in a diagonal direction between the first direction D1 and the second direction D2. The arrangement of the sub-pixels 21, 22, 23, and 24 in the third pixel 2a is not limited to FIG. 16, and other embodiments will be described later.

On a plane view, the fifth sub-pixel 21 may have a fifth length L5 in the first direction D1 and a sixth length L6 in the second direction D2. The sixth sub-pixel 22 may have a seventh length L7 in the first direction D1 and a sixth length L6 in the second direction D2. The seventh sub-pixel 23 may have a fifth length L5 in the first direction D1 and an eighth length L8 in the second direction D2. The eighth sub-pixel 24 may have a seventh length L7 in the first direction D1 and an eighth length L8 in the second direction D2.

The center point, which is a contact point of boundaries of each sub-pixel 21, 22, 23, and 24, may be provided within the third pixel 2a. For example, for the third pixel 1a, the center point may be located at the center or shifted slightly to the lower right. That is, for example, the fifth length L5 may be equal to or greater than the seventh length L7, and the sixth length L6 may be equal to or greater than the eighth length L8. Pixels that may be included in the display device 2000 are not limited to the third pixel 2a of FIG. 16, and other embodiments will be described later.

The fifth sub-pixel 21 and the eighth sub-pixel 24 may include a lower electrode 210, an insulating pattern 220, a second light source 320, an upper electrode 230, an intermediate layer 410, a second quantum dot pattern 530, a reflection pattern 540, and a second color filter 630.

The sixth sub-pixel 22 may include a lower electrode 210, an insulating pattern 220, a second light source 320, an upper electrode 230, an intermediate layer 410, a transparent pattern 510, a reflection pattern 540, and a first color filter 620.

The seventh sub-pixel 23 may include a lower electrode 210, an insulating pattern 220, a second light source 320, an upper electrode 230, an intermediate layer 410, a transparent pattern 510, a reflection pattern 540, and a third color filter 640.

The backplane 100 may be provided, and the lower electrode 210 and the insulating pattern 220 may be provided on the backplane 100.

The second light source 320 may be provided on the lower electrode 210. The upper electrode 230 may be provided on the second light source 320. The second light source 320 may be a blue-green light source.

The light source 320 may include, for example, a hole injection layer, a hole transport layer, a color emitting layer, an electron transport layer, and an electron injection layer. The color emitting layer may be, for example, a blue and green emitting layer. The light source 320 may further include a charge generation layer. The lower electrode 210, the light source 320, and the upper electrode 230 may form a color organic light emitting diode (OLED), and for example, may form a blue-green organic light emitting diode.

The intermediate layer 410 may be provided on the upper electrode 230. The transparent pattern 510 may be provided on the intermediate layer 410. Specifically, the transparent pattern 510 may be provided on the intermediate layer 410 of the sixth sub-pixel 22 and the seventh sub-pixel 23. The transparent pattern 510 may be provided in plurality, and multiple transparent patterns 510 may each be in contact with or connected to each other. On a plane view, the transparent patterns 510 may be disposed in a zigzag pattern in a diagonal direction between the first direction D1 and the second direction D2.

The quantum dot pattern 530 may be provided on the intermediate layer 410. A plurality of quantum dot patterns 530 may be provided, and may be spaced apart. Specifically, the second quantum dot pattern 530 may be provided within the fifth and eighth sub-pixels 21 and 24, and the second quantum dot pattern 530 may be a red quantum dot pattern. The quantum dot included in the second quantum dot pattern 530 may convert a wavelength of light emitted from the second light source 320 into a wavelength of red light. The quantum dot patterns 530 may each be spaced apart from the transparent patterns 510 in the first direction D1 or the second direction D2. On a plane view, the quantum dot patterns 530 may be disposed in a zigzag pattern in a diagonal direction.

The reflection pattern 540 may be provided on the intermediate layer 410. The reflection pattern 540 may be positioned between the transparent pattern 510 and the quantum dot pattern 530. The reflection pattern 540 may cover a side surface of the transparent pattern 510. The reflection pattern 540 may cover a side surface of the quantum dot pattern 530.

The color filter 620 and 640 may be provided on the transparent pattern 510. Specifically, the first color filter 620 may be provided on the transparent pattern 510 of the sixth sub-pixel 22, and the third color filter 640 may be provided on the transparent pattern 510 of the seventh sub-pixel 23. The first color filter 620 may be a green color filter, and the third color filter 640 may be a blue color filter. That is, the first color filter 620 may absorb blue light from the blue-green light emitted from the second light source 320 and selectively transmit green light. The third color filter 640 may absorb green light from the blue-green light emitted from the second light source 320 and selectively transmit blue light.

The color filter 630 may be provided on the quantum dot pattern 530. Specifically, the second color filter 630 may be provided on the second quantum dot pattern 530, and the second color filter 630 may be a red color filter. That is, the second color filter 630 may selectively transmit red light. The second color filter 630 may absorb undesired light that is not absorbed by the second quantum dot pattern 530, and thus improve the color reproducibility of the display device 2000.

The display device 2000 according to an embodiment of the inventive concept may have high color reproducibility by preventing color mixing of light through the reflection pattern 540 positioned between the transparent pattern 510 and the quantum dot pattern 530. The color filter 630 may be provided on the quantum dot pattern 530 to help achieve high color reproducibility. A plurality of transparent patterns 510 are provided diagonally between the first direction D1 and the second direction D2, and may thus increase process convenience. In addition, high light efficiency may be achieved by controlling the lengths L5, L6, L7, and L8 of the sub-pixels 21, 22, 23, and 24 in the first direction D1 and/or the second direction D2 according to the luminous efficiency of the light source 320 and the light conversion efficiency of the quantum dot patterns 530.

Hereinafter, a description will be given of pixels having different configurations that may be included in the display device 2000 according to some embodiments of the inventive concept.

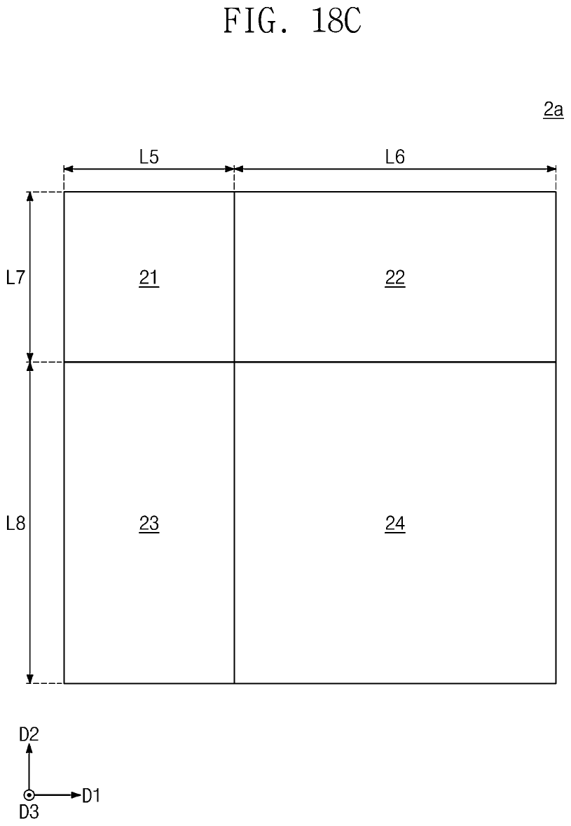

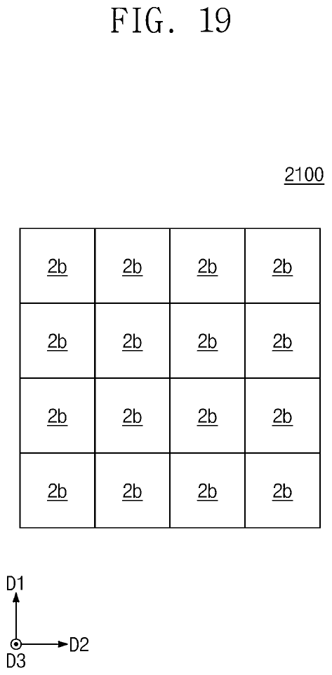

FIGS. 18A to 18C are plan views showing pixels that are included in a display device according to some embodiments of the inventive concept.

A third pixel 2a of FIG. 18A includes sub-pixels 11, 12, 13, and 14 that are identical to the sub-pixels 11, 12, 13, and 14 included in the third pixel 2a of FIGS. 14 and 16, but a sixth length L6 may be smaller than an eighth length L8.

A third pixel 2a of FIG. 18B includes sub-pixels 11, 12, 13, and 14 that are identical to the sub-pixels 11, 12, 13, and 14 included in the third pixel 2a of FIGS. 14 and 16, but a fifth length L5 may be smaller than a seventh length L7.

A third pixel 1a of FIG. 18C includes sub-pixels 11, 12, 13, and 14 that are identical to the sub-pixels 11, 12, 13, and 14 included in the third pixel 1a of FIGS. 14 and 16, but a fifth length L5 may be smaller than a seventh length L7, and a sixth length L6 may be smaller than an eighth length L8.

The center point may vary depending on the luminous efficiency of a second light source 320 and the luminous efficiency of the quantum dot pattern 530. A size relationship between the fifth length L5 and the seventh length L7 and a size relationship between the sixth length L6 and the eighth length L8 may be independent.

The display device 2000 according to an embodiment of the inventive concept may have high color reproducibility by preventing color mixing of light through the reflection pattern 540 positioned between the transparent pattern 510 and the quantum dot pattern 530. The color filter 630 may be provided on the quantum dot pattern 530 to help achieve high color reproducibility. A plurality of transparent patterns 510 are provided in a zigzag pattern diagonally between the first direction D1 and the second direction D2, and may thus increase process convenience. In addition, high light efficiency may be achieved by controlling the lengths L5, L6, L7, and L8 of the sub-pixels 11, 12, 13, and 14 in the first direction D1 and/or the second direction D2 according to the luminous efficiency of the second light source 320 and the light conversion efficiency of the quantum dot patterns 530.

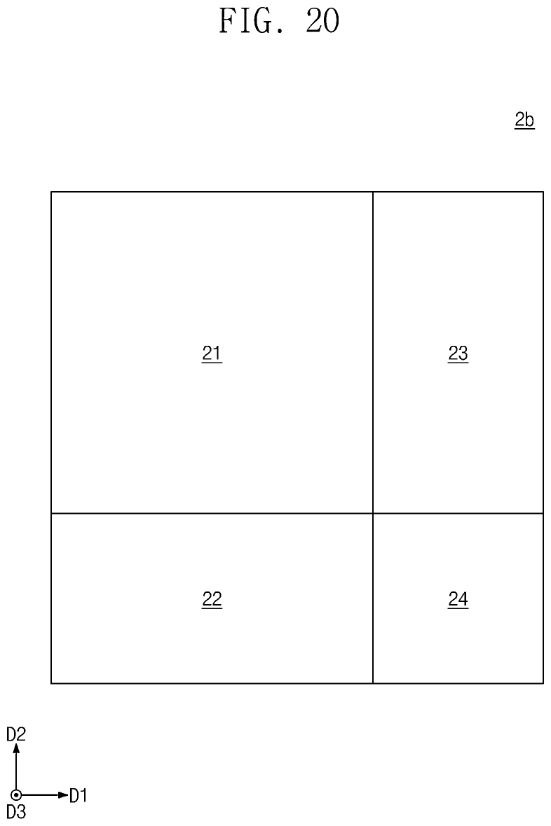

FIG. 19 is a plan view showing a display device according to some embodiments of the inventive concept. FIG. 20 is a plan view showing a pixel in FIG. 19.

Referring to FIGS. 19 and 20, a display device 2100 according to some embodiments of the inventive concept may be provided. The display device 2100 may include a plurality of fourth pixels 2b.

The fourth pixel 2b may include sub-pixels 21, 22, 23, and 24 that are identical to those of the third pixel 2a. In the fourth pixel 2b, the arrangement of the sub-pixels may be different from that of the third pixel 2a. Referring to FIG. 20, the fifth sub-pixel 21 and the sixth sub-pixel 22 may be positioned adjacent in the second direction D2, and the fifth sub-pixel 21 and the seventh sub-pixel 23 may be positioned adjacent in the first direction D1.

### [Method for Manufacturing a Display Device]

Hereinafter, a method for manufacturing a display device according to some embodiments of the inventive concept will be described.

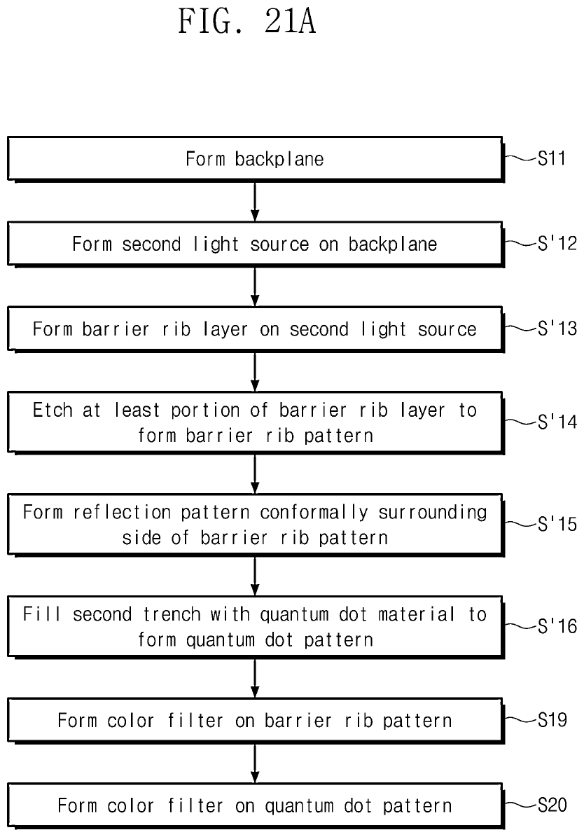

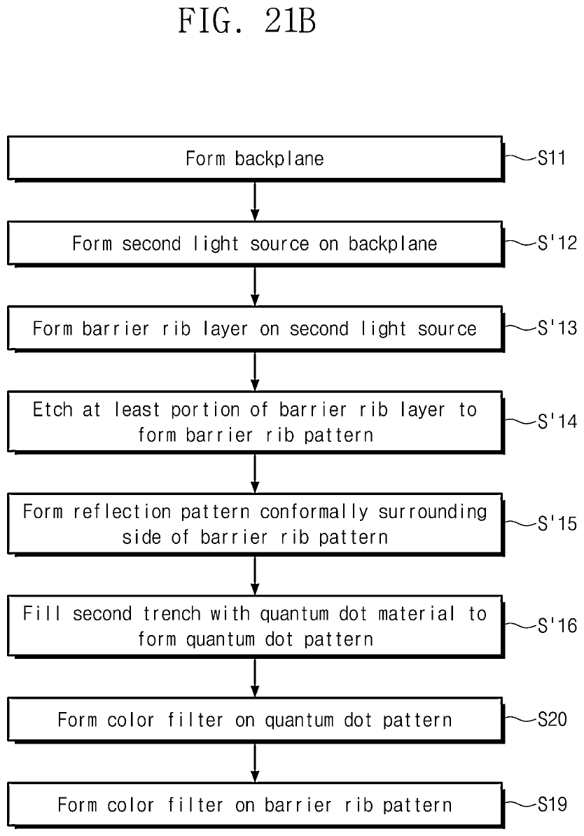

FIG. 21A shows a method for manufacturing a display device according to some embodiments of the inventive concept in FIG. 14.

A method for manufacturing display devices 2000 according to some embodiments of the inventive concept may include forming a backplane 100 (S11), forming a second light source 320 on the backplane 100 (S′12), forming a barrier rib layer (not shown) on the second light source 320 (S′13), etching at least a portion of the barrier rib layer (not shown) to form a transparent pattern 510 (S′14), forming a third trench T3 through the forming of the transparent pattern 510, and forming a reflection pattern 540 surrounding a side surface of the transparent pattern 510 (S′15), forming a fourth trench T4 through the forming of the reflection pattern 540, and filling the fourth trench T4 with a quantum dot material to form a quantum dot patterns 530 (S′16), forming color filters 620 and 640 on the transparent pattern 510 (S19), and forming a color filter 630 on the quantum dot pattern 530 (S20).

FIG. 21B shows a method for manufacturing a display device according to some embodiments of the inventive concept in FIG. 14.

Referring to FIG. 21B along with FIG. 21A, the forming of the color filters 620 and 640 on the transparent pattern 510 (S19) and the forming of the color filter 630 on the quantum dot pattern 530 (S20) may be performed regardless of temporal antecedent order. That is, as in FIG. 21A, the second color filter 630 may be formed after the forming of the first and third color filters 620 and 640, or as in FIG. 21B, the first and third color filters 620 and 640 may be formed after the forming of the second color filter 630.

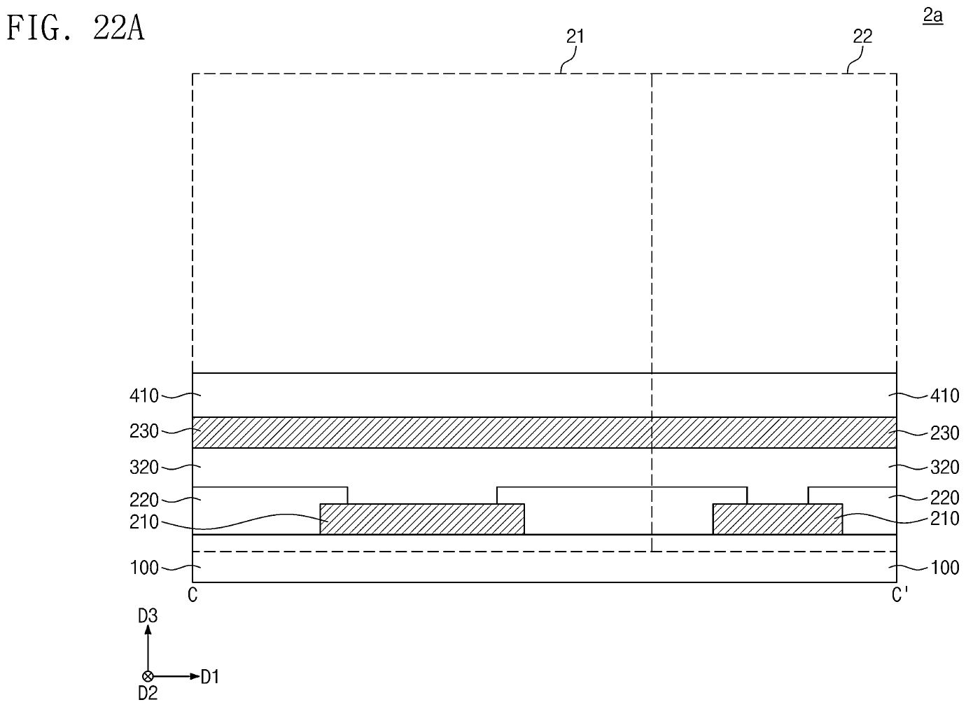

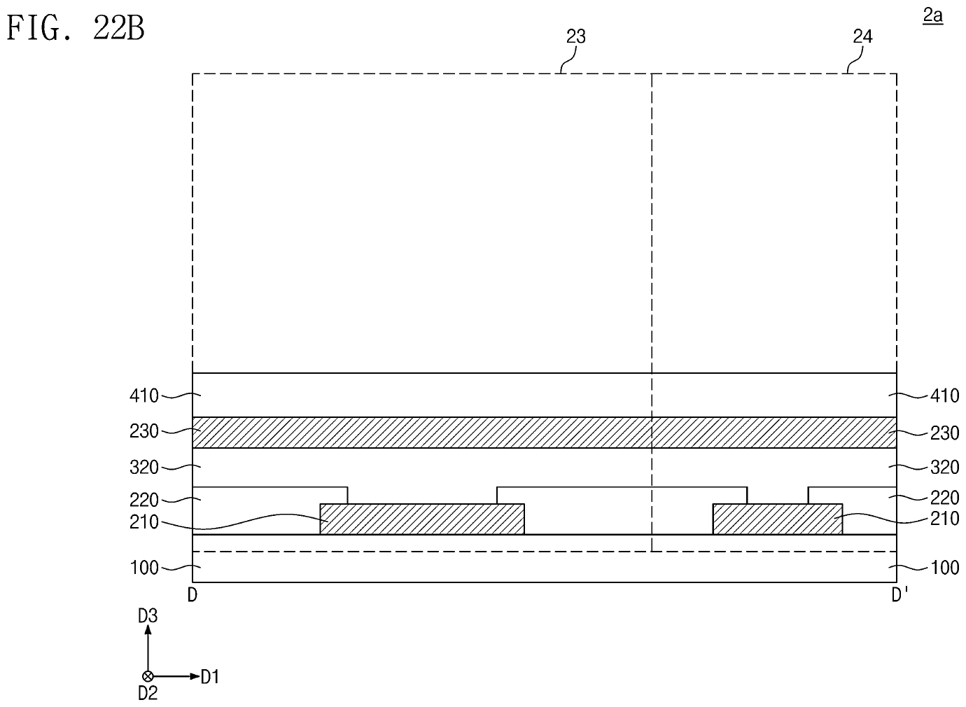

FIGS. 22A to 26B show a method for manufacturing a display device according to some embodiments of the inventive concept in FIG. 14.

Referring to FIGS. 22A and 22B, a backplane 100 may be formed. A lower electrode 210 may be provided on the backplane 100. An insulating pattern 220 may be formed on the backplane 100.

A second light source 320 may be formed on the lower electrode 210. The forming of the second light source 320 may include sequentially forming a hole injection layer, a hole transport layer, a color emitting layer, an electron transport layer, and an electron injection layer. The second light source 320 may be formed through a thermal deposition process.

An upper electrode 230 may be formed on the second light source 320. An intermediate layer 410 may be formed on the upper electrode 230.

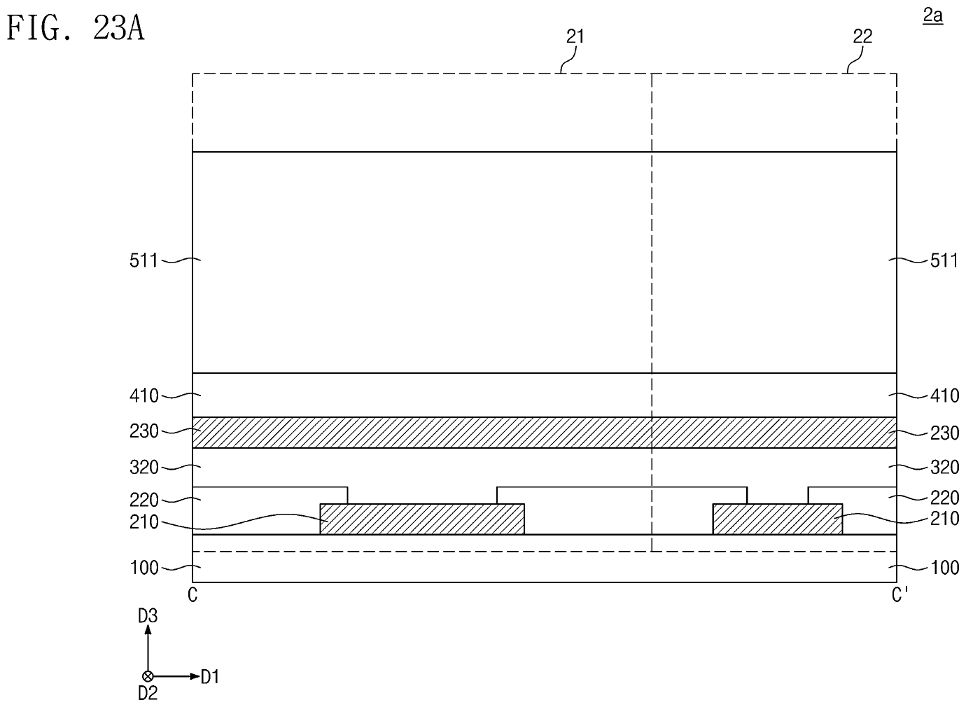

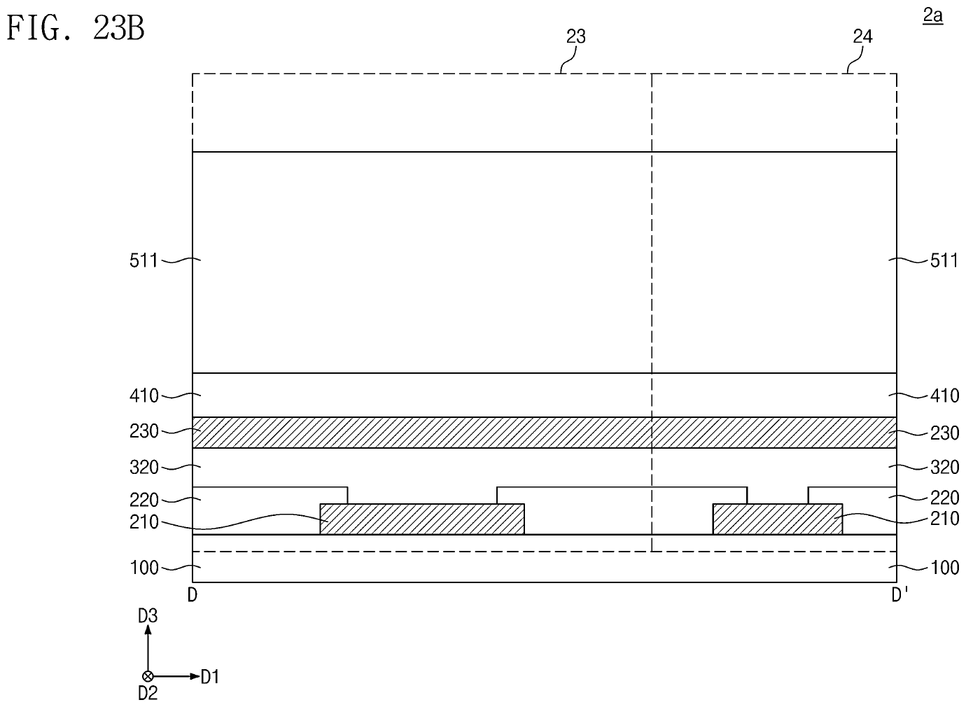

Referring to FIGS. 23A and 23B, a barrier rib layer 511 may be formed on the intermediate layer 410.

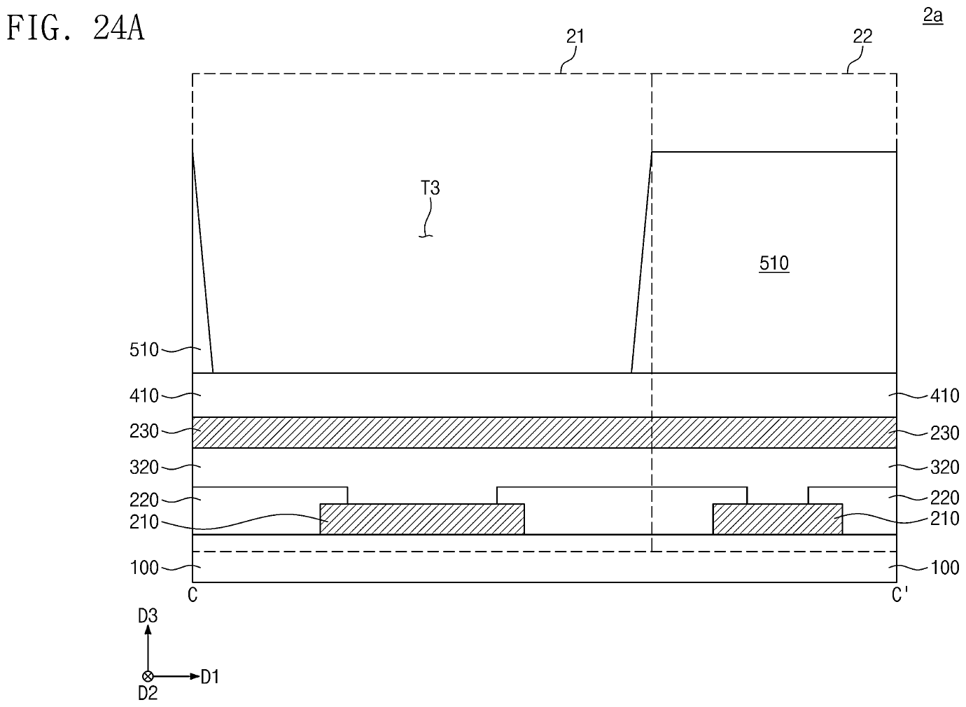

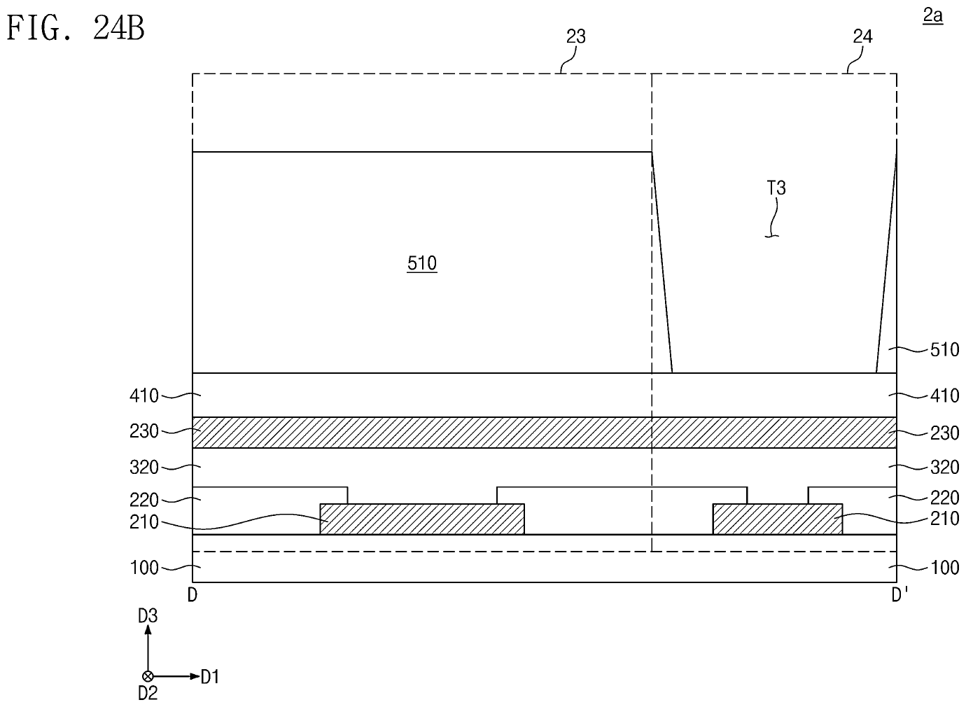

Referring to FIGS. 24A and 24B, at least a portion of the barrier rib layer 511 may be removed to form a transparent pattern 510.

The transparent pattern 510 may be provided in plurality. A third trench T3 may be formed between the transparent patterns 510. The third trench T3 may expose an upper surface of the intermediate layer 410. When being closer to the backplane 100, a width of the third trench T3 in the first direction D1 or the second direction D2 may remain constant or decrease.

The removing of at least a portion of the barrier rib layer 511 may include, for example, etching at least a portion of the barrier rib layer 511 and/or developing at least a portion of the barrier rib layer 511.

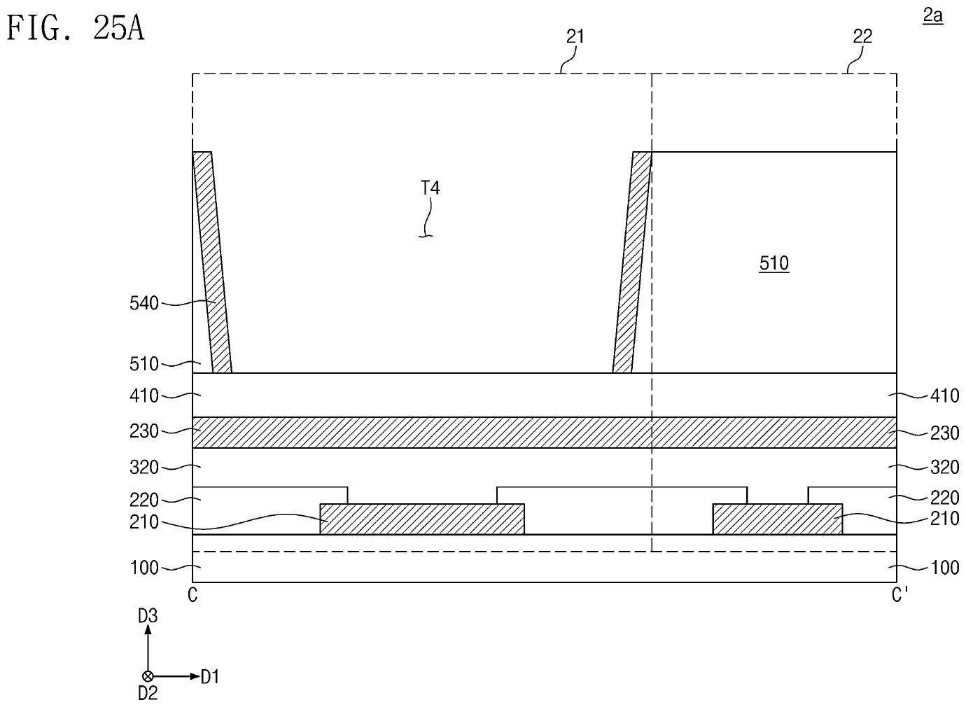

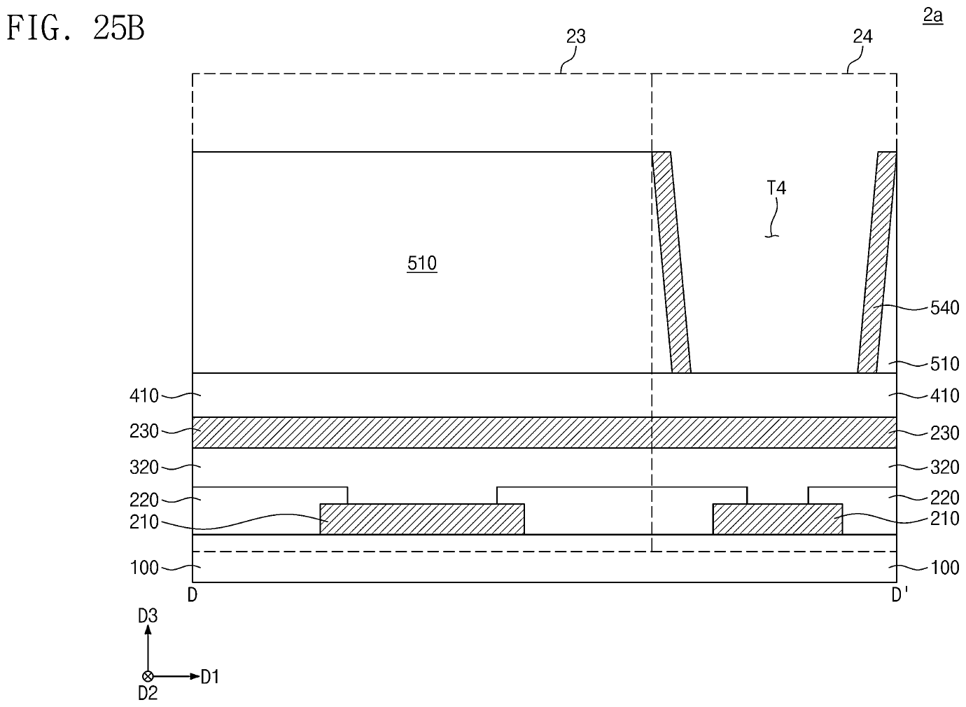

Referring to FIGS. 25A and 25B, a reflection pattern 540 may be formed on a side of the transparent pattern 510. The reflection pattern 540 may cover a side surface of the transparent pattern 510.

A fourth trench T4 may be formed through the forming of the reflection pattern 540. The fourth trench T4 may expose an upper surface of the intermediate layer 410. The fourth trench T4 may be positioned between the transparent patterns 510 that are spaced apart, and may be positioned between the reflection patterns 540 that are spaced apart. A width of the fourth trench T4 may be equal to or smaller than a width of the third trench T3. When being closer to the backplane 100, a width of the fourth trench T4 in the first direction D1 or the second direction D2 may remain constant or decrease.

The forming of the reflection pattern 540 may include, for example, forming a reflection layer (not shown) on an upper surface of the transparent pattern 510, a side surface of the transparent pattern 510, and an upper surface of the intermediate layer 410, and etching the reflection layer (not shown) formed on the upper surface of the transparent pattern 510 and the upper surface of the intermediate layer 410.

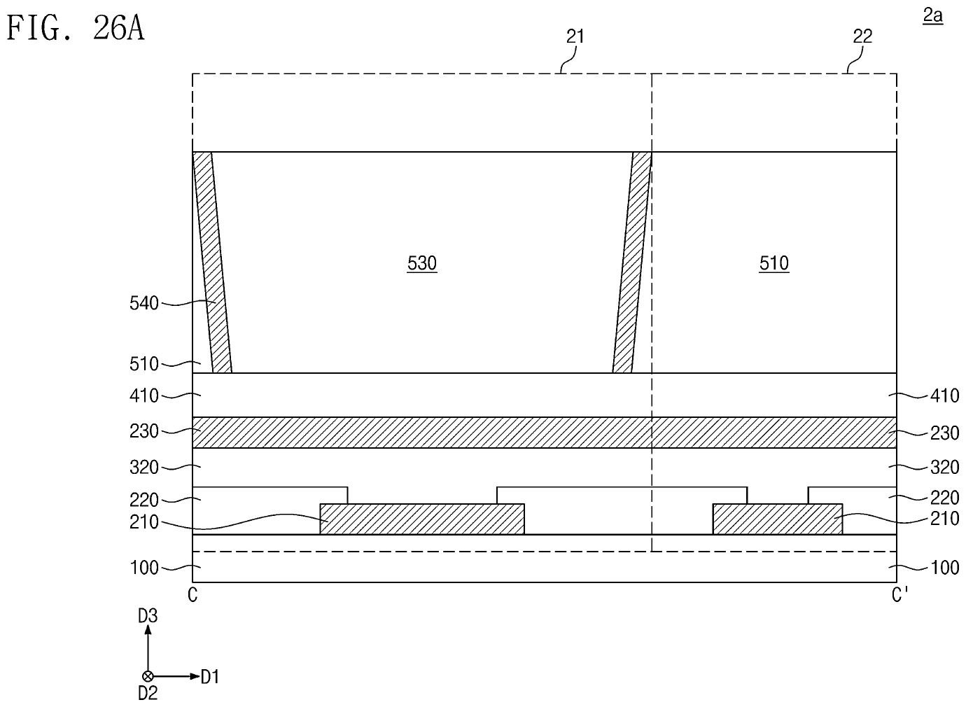

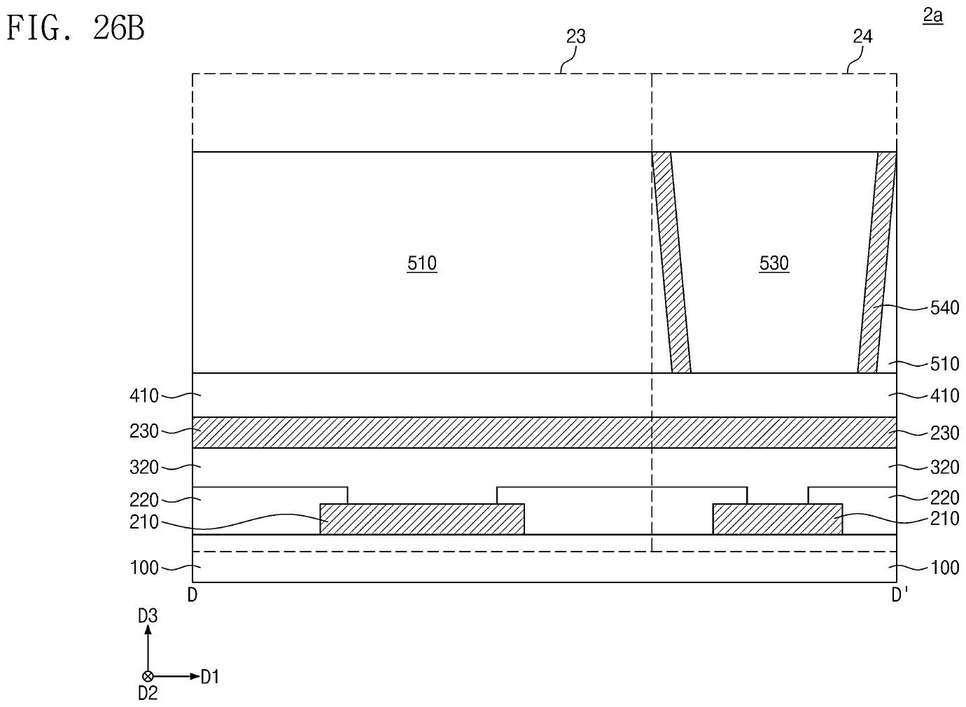

Referring to FIGS. 26A and 26B, a second quantum dot pattern 530 may be formed on the intermediate layer 410 of the fifth sub-pixel 21 and the eighth sub-pixel 24.

The forming of the second quantum dot pattern 530 may include, for example, selectively filling the fourth trench T4 of the fifth sub-pixel 21 and the eighth sub-pixel 24 with quantum dots. The filling of the fourth trench T4 with quantum dots may include, for example, forming a quantum dot layer (not shown) on an upper surface of the intermediate layer 410, a side surface of the reflection pattern 540, and an upper surface of the transparent pattern 510, and etching the quantum dot layer (not shown). For example, the etching of the quantum dot layer (not shown) may include planarizing the quantum dot layer (not shown). The planarizing of the quantum dot layer (not shown) may be performed until the upper surface of the transparent pattern 510 is exposed.

Referring back to FIGS. 17A and 17B, color filters 620 and 640 may be formed on the transparent pattern 510. Specifically, a first color filter 620 may be formed on the transparent pattern 510 of the sixth sub-pixel 22. A third color filter 640 may be formed on the transparent pattern 510 of the seventh sub-pixel 23. A second color filter 630 may be formed on the second quantum dot patterns 530. The forming of the first color filter 620, the second color filter 630, and the third color filter 640 may be performed regardless of temporal antecedent order.

The forming of the first color filter 620 may include, for example, selectively depositing the first color filter 620 on the transparent pattern 510 of the sixth sub-pixel 22. The forming of the second color filter 630 may include, for example, selectively depositing the second color filter 630 on the quantum dot pattern 530 of the fifth sub-pixel 21 and the eighth sub-pixel 24. The forming of the third color filter 640 may include, for example, selectively depositing the third color filter 640 on the transparent pattern 510 of the seventh sub-pixel 23. The forming of the first color filter 620, the forming of the second color filter 630, and the forming of the third color filter 640 may be performed, for example, through a photolithography process.

The method for manufacturing the display device 2000 according to an embodiment of the inventive concept may involve forming the transparent patterns 510 disposed in a zigzag pattern in a diagonal direction between the first direction D1 and the second direction D2, and then forming the reflection pattern 540, thereby preventing color mixing of light and achieving high color reproducibility.

A display device according to an embodiment of the inventive concept may exhibit high light efficiency, high color reproducibility, and high resolution through a quantum dot pattern, a transparent pattern, and a reflection pattern.

A method for manufacturing a display device according to an embodiment of the inventive concept may form a reflection pattern after forming a transparent pattern, thereby manufacturing a display device exhibiting high light efficiency, high color reproducibility, and high resolution.

Embodiments of the disclosure have been described with reference to the accompanying drawings. However, the disclosure may be implemented in other detailed forms without changing the technical spirit or necessary features thereof. It is therefore to be understood that the above-described embodiments are illustrative in all aspects and not restrictive.

What is claimed is:

1. A display device comprising:
a backplane;
a light source on the backplane;
a quantum dot pattern on the light source;
a transparent pattern disposed on the light source and spaced apart from the quantum dot pattern in a first direction parallel to an upper surface of the backplane; and
a reflection pattern between the quantum dot pattern and the transparent pattern.

2. The display device of claim 1, wherein the transparent pattern comprises at least one of an inorganic thin film, an organic thin film, or an organic-inorganic composite thin film, or a combination thereof.

3. The display device of claim 1, wherein the quantum dot pattern comprises a quantum dot,
the quantum dot including at least one of a Group II-VI compound, a Group III-V compound, a Group IV-VI compound, a Group I-III-VI compound, a Group IV element, or a Group IV compound, or a combination thereof.

4. The display device of claim 1, wherein the reflection pattern comprises at least one of a metal element, a metal alloy, a transition metal oxide, a metal nitride, or an inorganic thin film, or a combination thereof.

5. The display device of claim 1, wherein the light source is a blue light source.

6. The display device of claim 1, wherein the light source is a blue-green light source.

7. The display device of claim 1, further comprising:
a scattering pattern on the transparent pattern; and
a color filter on the quantum dot pattern.

8. The display device of claim 7, wherein the scattering pattern comprises a scattering agent,
the scattering agent including at least one of titanium oxide (TiO₂), zinc oxide (ZnO), tin oxide (SnO), silicon oxide (SiO), nickel oxide (NiO), magnesium oxide (MgO), zirconium oxide (ZrO₂), barium titanate (BaTiO₃), silicon carbide (SiC), boron nitride (BN), aluminum nitride (AlN), gallium nitride (GaN), zinc sulfide (ZnS), copper chloride (CuCl), strontium titanate (SrTiO₃), or lithium niobate (LiNbO₃), or a combination thereof.

9. The display device of claim 1, further comprising:
a blue color filter on the transparent pattern;
a green color filter on the transparent pattern; and
a red color filter on the quantum dot pattern.

10. The display device of claim 1, wherein:
the quantum dot pattern and the transparent pattern are provided in plurality; and
the quantum dot pattern and the transparent pattern are alternately disposed in the first direction.

11. The display device of claim 1, wherein the transparent pattern is configured such that a width of an upper surface in the first direction is equal to or greater than a width of a lower surface.

12. The display device of claim 1, wherein the quantum dot pattern is configured such that a width of a lower surface in the first direction is equal to or greater than a width of an upper surface.

13. The display device of claim 1, wherein:
the quantum dot pattern is provided in plurality, and the plurality of quantum dot patterns are spaced apart; and
the quantum dot pattern is disposed in a zigzag pattern diagonally between the first direction and a second direction perpendicular to the first direction.

14. A display device comprising:
a backplane; and
a plurality of pixels on the backplane,
wherein the plurality of pixels each include a first sub-pixel and a second sub-pixel,
the first sub-pixel including:
a quantum dot pattern on the backplane;
a reflection pattern surrounding a side surface of the quantum dot pattern; and
a first color filter on the quantum dot pattern, and
the second sub-pixel including the transparent pattern on the backplane,
wherein the quantum dot pattern and the transparent pattern are spaced apart with the reflection pattern therebetween.

15. The display device of claim 14, wherein the second sub-pixel further comprises a scattering pattern on the transparent pattern.

16. The display device of claim 14, wherein the second sub-pixel further comprises a second color filter on the transparent pattern, and
the first color filter and the second color filter are different in color.

17. A display device comprising:
a backplane;
a light source on the backplane;
a quantum dot pattern on the light source;
a transparent pattern disposed on the light source and spaced apart from the quantum dot pattern in a first direction parallel to an upper surface of the backplane; and
a reflection pattern between the quantum dot pattern and the transparent pattern,
wherein:
the quantum dot pattern is provided in plurality, and the plurality of quantum dot patterns are spaced apart and disposed in a zigzag pattern diagonally between the first direction and a second direction perpendicular to the first direction;
the reflection pattern is provided in plurality, and the plurality of reflection patterns are spaced apart and disposed in a zigzag pattern diagonally; and
the transparent pattern is provided in plurality, and the plurality of transparent patterns have lower surfaces connected and upper surfaces disposed in a zigzag pattern diagonally.

18. The display device of claim 17, wherein the quantum dot pattern and the transparent pattern are alternately disposed in the first direction and the second direction.

19. The display device of claim 17, further comprising:
a scattering pattern on the transparent pattern; and
a color filter on the quantum dot pattern,
wherein:
the quantum dot pattern includes a green quantum dot pattern and a red quantum dot pattern; and
the color filter includes a green color filter and a red color filter.

20. The display device of claim 17, further comprising:
a first color filter on the transparent pattern; and
a second color filter on the quantum dot pattern,
wherein the first color filter and the second color filter are different in color.
